(19) United States
(12) Patent Application Publication
(10) Pub. No.: US 2009/0246964 A1
(43) Pub. Date: Oct. 1, 2009

(54) Etching process for phase-change films

(75) Inventors: Huai-Yu Cheng, Hsinchu (TW); Yi-Chou Chen, Hsinchu (TW)

Correspondence Address: J C PATENTS, INC., 4 VENTURE, SUITE 250, IRVINE, CA, 92618, US

(73) Assignee: MACRONIX International Co., Ltd., Hsinchu (TW)

(21) Appl. No.: 12/290,560

(22) Filed: Oct. 31, 2008

Related U.S. Application Data
(60) Provisional application No. 61/070,730, filed on Mar. 25, 2008.

(51) Int. Cl. H01L 21/465

(52) U.S. Cl. 438/710; 257/E21.485

(57) ABSTRACT

The invention is directed to a method for etching a phase change material layer comprising steps of providing a phase change material layer and performing a first etching process on the phase change material layer. The etching process is performed with an etchant comprising a fluoride-based gas with a concentration of the fluoride-based gas up to 85% of a total volume of the etchant.

### CROSS-REFERENCE TO RELATED APPLICATION

This application claims the priority benefit of U.S. provisional application Ser. No. 61/070,730, filed Mar. 25, 2008. The entirety of the above-mentioned patent application is hereby incorporated by reference herein and made a part of this specification.

### BACKGROUND OF THE INVENTION

1. Field of Invention

The present invention relates to high density memory devices based on phase change memory materials, and more particularly to processes for etching phase change memory materials.

2. Description of Related Art

Phase change based memory materials, like chalcogenide based materials and similar materials, can be caused to change phase between an amorphous state and a crystalline state by application of electrical current at levels suitable for implementation in integrated circuits. The generally amorphous state is characterized by higher electrical resistivity than the generally crystalline state, which can be readily sensed to indicate data. These properties have generated interest in using programmable resistive material to form nonvolatile memory circuits, which can be read and written with random access.

The change from the amorphous to the crystalline state is generally a lower current operation. The change from crystalline to amorphous, referred to as reset herein, is generally a higher current operation, which includes a short high current density pulse to melt or breakdown the crystalline structure, after which the phase change material cools quickly, quenching the molten phase change material and allowing at least a portion of the phase change material to stabilize in the amorphous state. It is desirable to minimize the magnitude of the current needed to cause transition of phase change material.

The magnitude of the current needed for reset can be reduced by reducing the size of the phase change material element in the cell and/or the contact area between electrodes and the phase change material, so that higher current densities are achieved with small absolute current values through the phase change material.

One approach to reducing the size of the phase change element in a memory cell is to form small phase change elements by etching a layer of chalcogenide material. Etchants for etching chalcogenides include Ar/Cl12, Ar/BCl3, Ar/HBr, and Ar/CHF3/O2.

However, attempts to reduce the size of the phase change element by etching can result in damage of the chalcogenide material due to the non-uniform reactivity with the etchants which can cause the formation of voids, compositional and bonding variations, and the formation of nonvolatile by-products. This damage can result in variations in shape and uniformity of the phase change elements across an array of memory cells, resulting in electrical and mechanical performance issues for the cell. Additionally, the high etching rate of chalcogenides by Cl2 gas makes the etching process difficult to control, especially in forming small phase change elements.

It is therefore desirable to provide techniques and methods which address the damage problems described above, as well as techniques and methods for etching phase change materials at controlled etch rates, thereby allowing for the formation of phase change elements having very small feature sizes.

### SUMMARY OF THE INVENTION

Accordingly, the present invention is to provide a method for etching a phase change material layer with a relatively slow etching rate for defining the phase change material layer.

The present invention is also to provide a method for etching a phase change material layer with a relatively smooth top surface and a relatively small dimension.

To achieve these and other advantages and in accordance with the purpose of the invention, as embodied and broadly described herein, the invention provides a method for forming a phase change material layer. The method comprises steps of providing a phase change material layer and etching the phase change material layer with an etchant. The etchant comprises a fluoride-based gas having a concentration up to 85% of a total volume of the etchant.

According to one embodiment of the present invention, the method further comprises etching the phase change material layer with plasma. The plasma is selected from a group including helium plasma, argon plasma, neon plasma and the combination thereof. A porous layer and a fluoride byproduct are formed over the etched phase change material layer during the etching step with the etchant. The porous layer and the fluoride byproduct are removed during the etching step with plasma.

According to one embodiment of the present invention, the etchant further comprises an inert gas and nitrogen. The inert gas is selected from a group including Argon, Helium, Neon and the combination thereof. The concentration of the inert gas is about 7% to 95%. The concentration of the nitrogen is about 5% to 85%.

According to one embodiment of the present invention, the fluoride-based gas is selected from a group including difluoromethane, trifluoromethane, tetrafluoromethane and the combination thereof.

According to one embodiment of the present invention, the step for etching the phase change material layer is performed at a working pressure less than 1 Pa.

According to one embodiment of the present invention, an applied frequency of the step for etching the phase change material layer is about 1˜13.6 MHz. A forward power of the step for etching the phase change material layer is about 600˜1200 W. A backward power of the step for etching the phase change material layer is about 0˜100 W.

The invention also provides a method for forming a phase change material layer. The method comprises steps of providing a phase change material layer and etching the phase change material layer with an etchant comprising a fluoride-based gas having a concentration less than 15% of a total volume of the etchant.

According to one embodiment of the invention, the etchant further comprises an inert gas and nitrogen. Also, the inert gas is selected from a group including Argon, Helium, Neon and the combination thereof.

According to one embodiment of the invention, the fluoride-based gas is selected from a group including difluoromethane, trifluoromethane, tetrafluoromethane and the combination thereof.

According to one embodiment of the invention, the step for etching the phase change material layer is performed at a working pressure less than 1 Pa.

According to one embodiment of the invention, the etching rate of the step for etching the phase change material layer is about 1.5˜4 nm/s.

According to one embodiment of the invention, an applied frequency of the step for etching the phase change material layer is about 1˜13.6 MHz.

According to one embodiment of the invention, a forward power of the step for etching the phase change material layer is about 600˜1200 W.

According to one embodiment of the invention, a backward power of the step for etching the phase change material layer is about 0˜100 W.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a prior art memory cell.

FIG. 2 illustrates the cross-section of amorphous GST after etching for 30 seconds using 50% CF4 showing that porous structures will form during the process.

FIG. 3 illustrates the cross-section after etching amorphous GST for 30 seconds using CF4/Ar/N2 with 14% CF4.

FIG. 4A illustrates cross-sections of amorphous GST having an initial thickness of approximately 500 nm etched for 30 seconds using CF4/Ar/N2 with CF4 concentrations of 50%.

FIG. 4B illustrates cross-sections of amorphous GST having an initial thickness of approximately 500 nm etched for 30 seconds using CF4/Ar/N2 with CF4 concentrations of 35.7%.

FIG. 4C illustrates cross-sections of amorphous GST having an initial thickness of approximately 500 nm etched for 30 seconds using CF4/Ar/N2 with CF4 concentrations of 21.4%.

FIG. 4D illustrates cross-sections of amorphous GST having an initial thickness of approximately 500 nm etched for 30 seconds using CF4/Ar/N2 with CF4 concentrations of 14.3%.

FIG. 5 illustrates the etching rate of amorphous Ge2Sb2Te5 versus the CF4 concentration after 30 seconds, showing that the etching rate can be controlled by the CF4 concentration.

FIG. 6 illustrates etched GST in the amorphous state with an etching rate of 3.93 nm/s after 30 seconds using CF4/Ar/N2.

FIG. 7 illustrates etched GST in the crystalline state with an etching rate of 3.8 nm/s.

FIG. 8 illustrates the cross-section of amorphous GST after etching using 21% CF4, 71% Ar, and 7% N2 for 15 s showing that porous structures having voids will form during the process.

FIG. 9 illustrates the cross-section after etching at 21% CF4 for 15 s and then 100% Ar for 50 s.

FIGS. 10-14 illustrate the binding energy vs intensity of as deposited GST, etched GST using 21% CF4 for 15 s, etched GST using 21% CF4 followed by 100% Ar for 50 s, and etched GST using 21% CF4 for 30 s.

FIG. 15A shows cross-sectional views of GST etched using CF4/Ar/N2 with CF4 concentrations of 50%.

FIG. 15B shows cross-sectional views of GST etched using CF4/Ar/N2 with CF4 concentrations of 35.7%.

FIG. 15C shows cross-sectional views of GST etched using CF4/Ar/N2 with CF4 concentrations of 21.4%.

FIG. 15D shows cross-sectional views of GST etched using CF4/Ar/N2 with CF4 concentrations of 14.3%.

FIG. 15E illustrates the etching rate of GST versus CF4 concentration, showing that the etching is controllable with different CF4 concentrations.

FIGS. 16A through 16C illustrate the etching rate of 50% CF4 for times of 10 s, 20 s, and 30 s respectively.

FIGS. 17A through 17C illustrate the etching rate of 14.3% CF4 for times of 10 s, 30 s, and 60 s.

FIG. 18 illustrates the XPS Spectra of GST films as-deposited (amorphous), after etching for 10 s, etching for 50 s, and etching for 170 s.

FIG. 19 illustrates the XPS Spectra of Sb 3d.

FIG. 20 illustrates the XPS Spectra of Te3d.

FIG. 21 illustrates a simplified cross-sectional view of the structure used for measuring the IV characteristics of amorphous GST.

FIG. 22 illustrates a cross-sectional view of one of the actual devices.

FIG. 23 illustrates the measured voltage versus resistance characteristics of original GST, etched GST using CF4/Ar/N2 with 14.3% CF4, etched GST using pure Ar etching, and etched GST using 14.3% CF4 without N2.

FIG. 24 shows the measured resistivity of each for a voltage of 0.1 Volts.

FIG. 25A illustrates cross-sectional views of crystalline GST etched using 14.3% CF4 at 0 second.

FIG. 25B illustrates cross-sectional views of crystalline GST etched using 14.3% CF4 after 20 second.

FIG. 25C illustrates cross-sectional views of crystalline GST etched using 14.3% CF4 after 30 seconds.

FIG. 25D illustrates cross-sectional views of crystalline GST etched using 14.3% CF4 after 60 seconds.

FIG. 26 illustrates 2θ versus intensity at 0 seconds, 30 seconds of etching, and 60 seconds of etching, and the (111), (200, (220), and (222) numbers in the figure indicate the planes of the crystal.

FIG. 27 is a cross-section of amorphous GST etched using 100% Ar resulting in an etching rate of 1.5 nm/s.

FIG. 28 is a cross-section of amorphous GST etched using CF4/Ar/N2 as described herein, resulting in an etching rate of 2.1 nm/s.

FIG. 29 illustrates the XPS data of the as-deposited GST and the etched GST after Ar etching for 20 s.

FIG. 30 illustrates a cross-section of crystalline GST etched using Pure Ar, 1000/60, 1 Pa, 50 s resulting in an etch rate of 0.68 nm/s, illustrating the etching damage by Ar bombardment.

FIG. 31 illustrates a cross-section of crystalline GST etched using CF4/Ar/N2 with 14.3% CF4, 1000/60, 1 Pa, 60 s resulting in an etch rate of 3.8 nm/s and a smooth surface.

FIG. 32 shows 2θ versus intensity for crystalline GST and for crystalline GST after etching treatment by Ar plasma.

FIG. 33 shows the change in lattice constant c after the Ar plasma etching.

FIG. 34 shows the crystallization behavior of amorphous and crystalline GST at 0 s and after 60 s of etching using CF4/Ar/N2 with 14% CF4 as described herein.

FIG. 35 illustrates the process for forming nano-sized patterns using the techniques described herein.

FIGS. 36A-36F show the results of GST lines with features sizes from 1 μm to 50 nm successfully manufactured using CF4/Ar/N2 as described herein.

FIG. 37 illustrates a bridge type cell illustrating the types of devices that can be formed using the techniques described herein and is milled by Ar only.

FIG. 38 illustrates a cross-sectional view of patterned GST using CF4 etching as described herein having a thickness of 30 nm using PR of Ma-N2405, baked at 135 degrees C., resulting in lines having a critical dimension of approximately 50 nm.

### DESCRIPTION OF THE PREFERRED EMBODIMENTS

The following description of the disclosure will typically be with reference to specific structural embodiments and methods. It is to be understood that there is no intention to limit the disclosure to the specifically disclosed embodiments and methods, but that the disclosure may be practiced using other features, elements, methods and embodiments. Preferred embodiments are described to illustrate the present disclosure, not to limit its scope, which is defined by the claims. Those of ordinary skill in the art will recognize a variety of equivalent variations on the description that follows. Like elements in various embodiments are commonly referred to with like reference numerals.

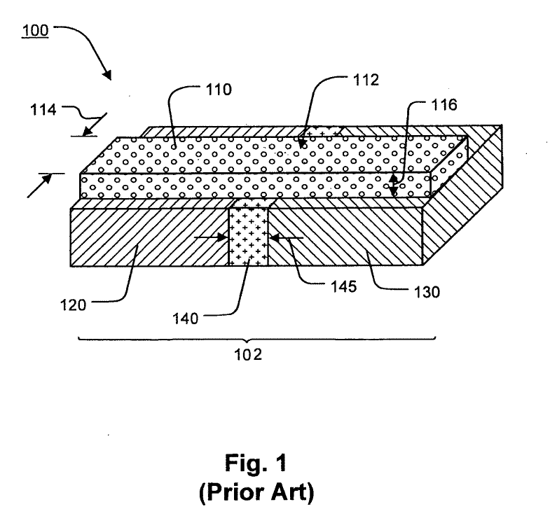

FIG. 1 illustrates a prior art memory cell 100 having an electrode layer 102 and a bridge 110. The electrode layer 102 comprises a first electrode 120, a second electrode 130 and a dielectric spacer 140 formed therein. Further, the bridge 110 of phase change memory material coupled to the first and the second electrodes 120, 130. The first electrode 120 may, for example, be coupled to a terminal of an access device such as a diode or transistor, while the second electrode 130 may be coupled to a bit line. A dielectric spacer 140 having a width 145 separates the first and second electrodes 120, 130. The bridge 110 extends across the dielectric spacer 140 and contacts the first and second electrodes 120, 130, thereby defining an inter-electrode path between the first and second electrodes 120, 140 having a path length defined by the width 145 of the dielectric spacer 140. In operation, voltages on the first electrode 120 and the second electrode 130 can induce a current to flow from the first electrode 120 to the second electrode 130, or vice versa, via the bridge 110. The active region 112 is the region of the bridge 110 in which the memory material is induced to change between at least two solid phases.

The bridge 110 can be formed by depositing a layer of phase change material on the electrodes 120, 130 and dielectric spacer 140 and etching the layer of phase change material using an etch mask/patterned mask layer. It is desirable to minimize the thickness 116 and width 114 of the bridge 110 and the width 145 of the dielectric spacer 140, so that higher current densities are achieved with small absolute current values through the bridge 110.

However, problems have arisen in manufacturing such devices having a small width 114 due to damage of the material of bridge 110 from the non-uniform reactivity of the phase change material with etchants which can cause the formation of voids, compositional and bonding variations during the etching process, and the formation of nonvolatile by-products of the etchant and the phase change material. This damage can result in variations in shape and uniformity of the phase change elements across an array of memory cells, resulting in electrical and mechanical performance issues for the cell and thus limiting the minimum obtainable width 114.

It is therefore desirable to provide techniques and methods which address the damage problems described above, as well as techniques and methods for etching phase change materials at controlled etch rates, thereby allowing for the formation of phase change elements having very small feature sizes.

### A One-Step Etching Process for Damage Free Phase-Change Films:

The present invention provides suitable etchants for dry-etching of phase change materials. The CF4 based etchant can achieve very low etching rate for phase change films and thus is suitable for manufacturing nano-sized patterns and overcoming the bombardment damages in pattern shape and uniformity.

As described above chalcogenides can be easily etched with many kinds of gas, e.g. Cl2, HBr, etc., due to the chemical nature of chalcogenides. Due to the high etching rate of chalcogenide by Cl2 gas, the process becomes difficult to control, especially in small dimensional patterns.

The non-uniform reactivity in chalcogenides with etchants causes the formation voids, and composition and bonding variation during the etching process.

This invention can reduce the etch rate for chalcogenide materials, and provides a method to fabricate very smooth and uniform chalcogenide film and overcome the problems described above.

The GST films in the amorphous and crystalline state exhibit different reactivity with Cl2 gas, such as the etching rate. The damage of films by Ar bombardment in crystalline state is serious. This invention provides a method to etch crystalline film as good as amorphous ones.

The present invention proposes using fluoride-based mixture gas as an etchant to define the phase change material layer to be the bridge. The fluoride-based mixture gas comprises the fluoride-based gas, inert gas and nitrogen and the combination thereof. Also, the fluoride-based gas can be, for example but not limited to, difluoromethane (CH2F2), trifluoromethane (CHF3), tetrafluoromethane (CF4) and the combination thereof and the inert gas comprises Argon, Helium, Neon and the combination thereof. Moreover, the concentration of the fluoride-based gas is lower than 15% of the total volume of the etchant. Furthermore, a working pressure of the etching process is less than 1 Pa. The etching process is performed at room temperature with an applied frequency of about 1˜13.6 MHz, with a power of about 600˜1200 W forward, and about 0˜100 W backward. Also, the etching rate of the fluoride-based mixture gas with concentration of the fluoride-based gas lower than 15% for etching the phase change material layer is about 1.5˜4 nm/s. The ratio of a flow rate of the nitrogen to a flow rate of the inert gas is about 7˜10%. The flow rate of the fluoride-based gas is about 4˜15 sccm. The flow rate of the inert gas is about 45˜85 sccm. The flow rate of the nitrogen is about 0˜5 sccm. The time for performing the etching process is about 20 s˜60 s. In one embodiment of the invention presented below the N2 gas flow rate is maintained at 5 sccm (standard cubic centimeters per minute) unless otherwise noted, and the total flow rate of N2, Ar, and CF4 is 70 sccm. For example, the 14.3% CF4 flow contains 5 sccm (7%) of N2, 10 sccm of CF4, and 55 sccm of Ar. As another example for 7% of CF4, the Ar is 60 sccm (85%) and N2 is 5 sccm (7%). Alternatively the N2 rate may also be changed. The use of N2 results in a better sidewall formation for the patterned phase change material. The etching rate is one of the limits on the lower range of CF4 that may be used in some embodiments. Others include that CF4 the desired surface roughness and a better control of the vertical profile.

The present invention can be used for crystalline and amorphous state chalcogenides using, for example, PMMA/HSQ/ma-N2405 photo-resists. In the CF4/Ar/N2 recipe described herein HSQ photoresist can be removed during etching, but with N2 the etching rate on HSQ may be slower. This recipe for etching chalcogenides can provide smooth, uniform, and non-voids structures having low concentrations of nonvolatile by-products such as SbF3.

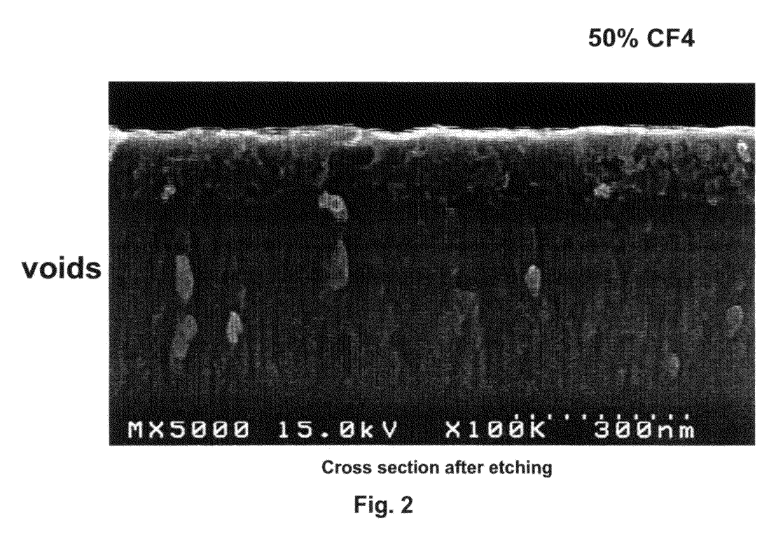

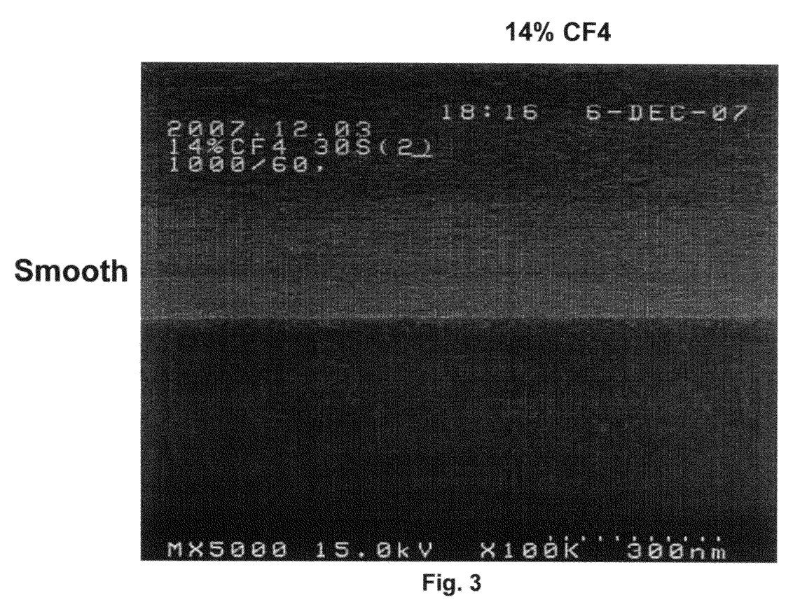

Chalcogenide films are not etched at the same rate. FIG. 2 illustrates the cross-section of amorphous GST after etching for 30 seconds using 50% CF4 showing that porous structures will form during the process. FIG. 3 illustrates the cross-section after etching amorphous GST for 30 seconds using CF4/Ar/N2 with 14% CF4. It is believed that when the CF4 concentration is low enough the porous layer is removed by the physical bombardment, and thus the porous layer of etched films can be removed if the concentration of CF4 is tunable to below 15%.

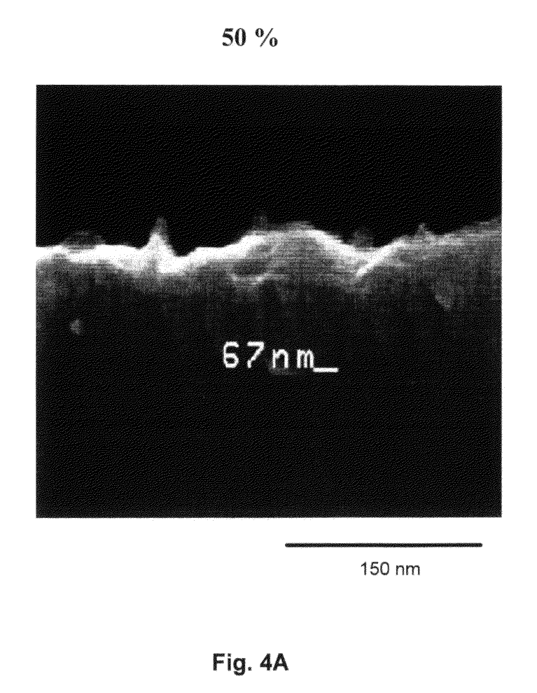

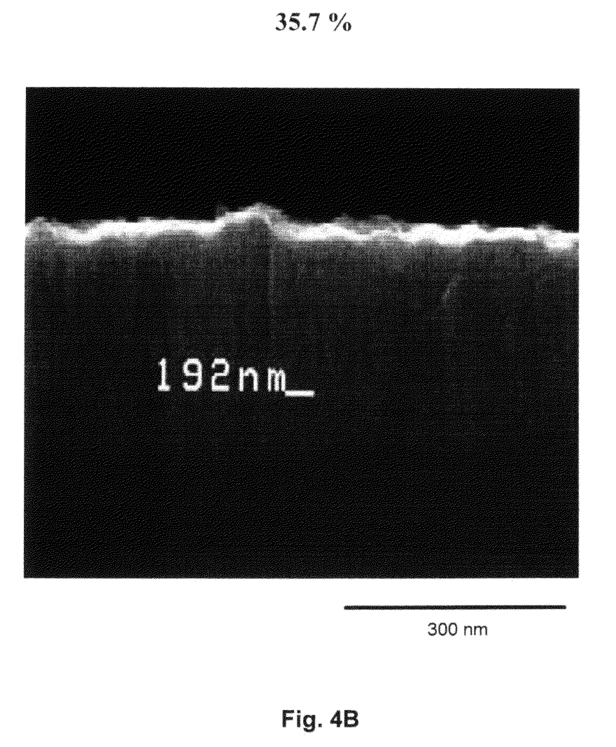

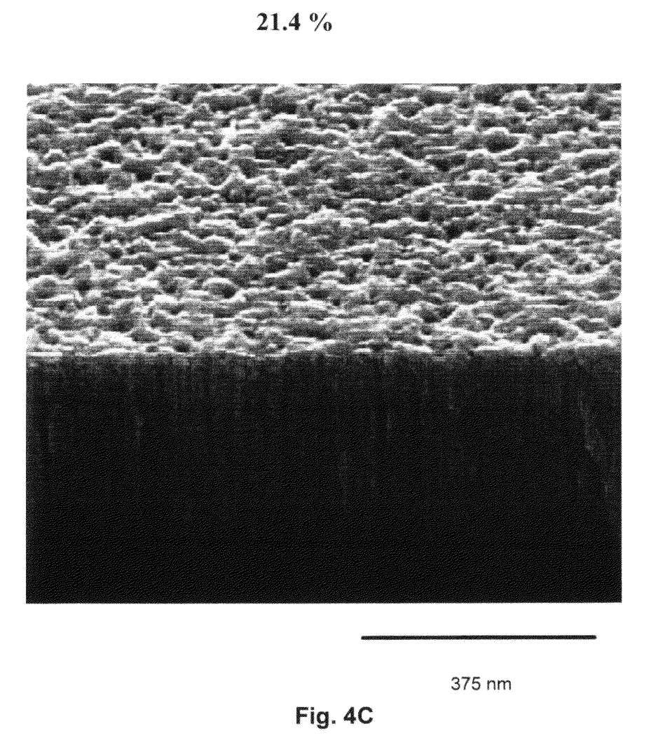

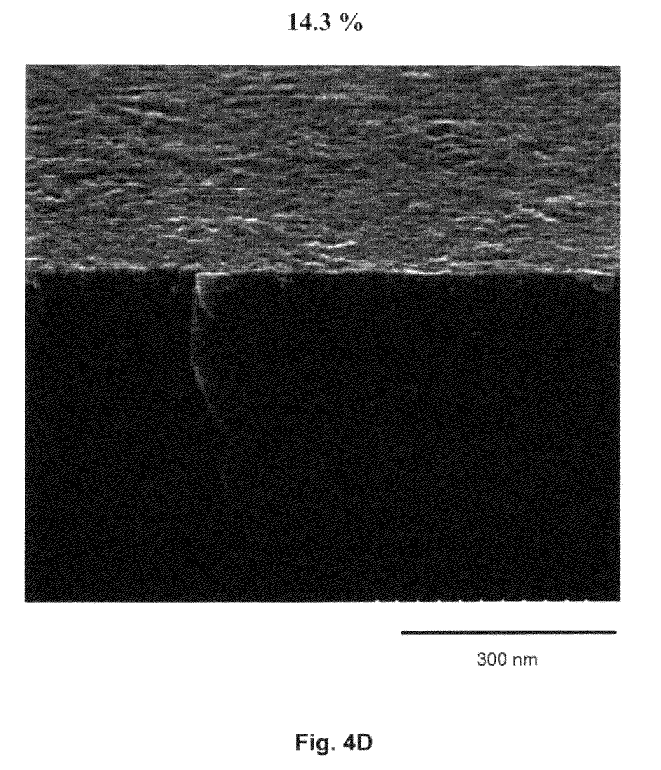

FIGS. 4A-4D illustrate cross-sections of amorphous GST having an initial thickness of approximately 500 nm etched for 30 seconds using CF4/Ar/N2 with CF4 concentrations of 50%, 35.7%, 21.4%, and 14.3% respectively. As can be seen in FIGS. 4A-4D, the surface roughness of the etched GST seriously depends upon the CF4 concentration. The lower the concentration is, the more uniform and intact the surface we can get.

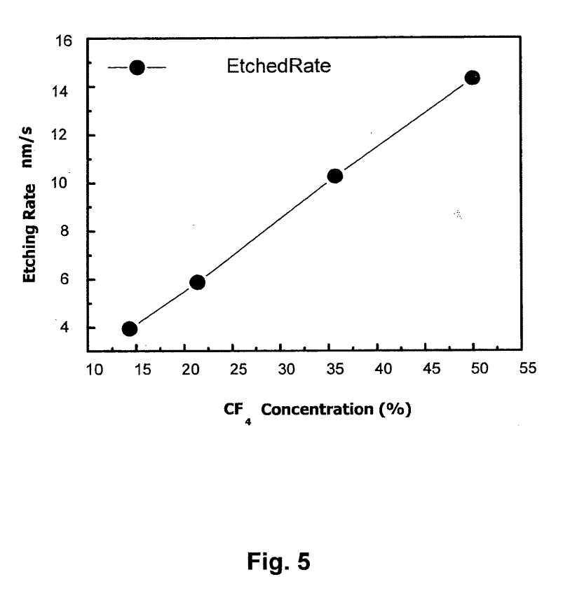

FIG. 5 illustrates the etching rate of amorphous Ge2Sb2Te5 versus the CF4 concentration after 30 seconds, showing that the etching rate can be controlled by the CF4 concentration. As shown in the Table below, the etching rate is significantly lower than other etchants such as Cl2 or HBr even in the same concentrations.

| Recipe | Etching Rate (nm/s) |
|---|---|
| 15% CHF₃ | 5.4 |
| 15% HBr | 6.67 |
| 15% Cl₂ | 6.5 |
| 14.3% CF₄ | 3.93 |
| 100% Ar | 1.5 |

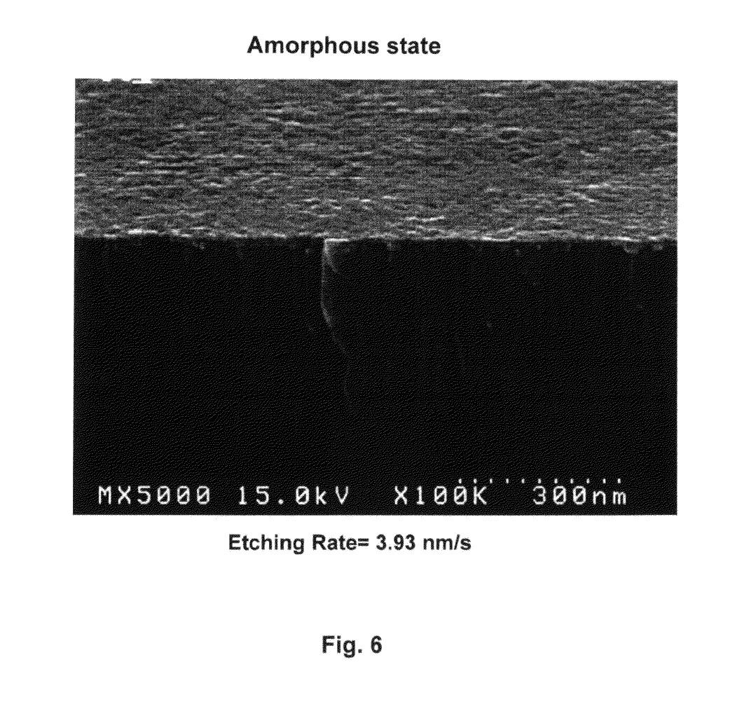

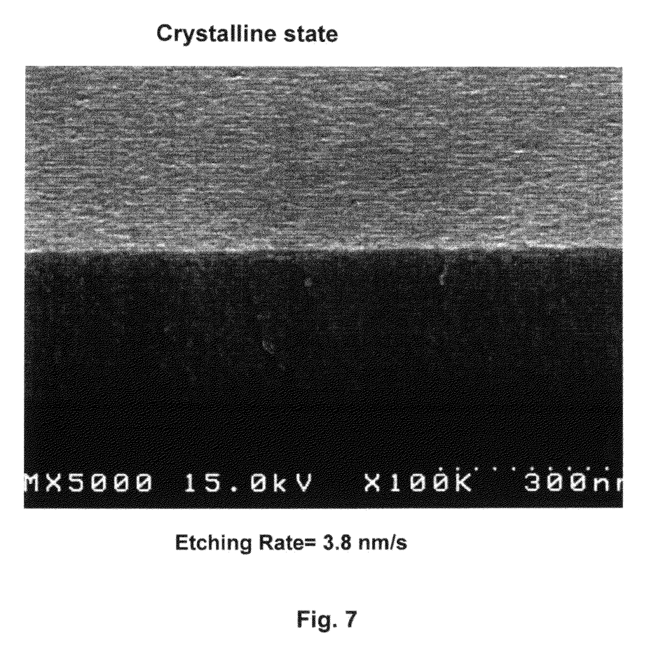

FIG. 6 illustrates etched GST in the amorphous state with an etching rate of 3.93 nm/s after 30 seconds using CF4/Ar/N2, while FIG. 7 illustrates etched GST in the crystalline state with an etching rate of 3.8 nm/s. Thus the etching rates for amorphous GST and crystalline GST are almost the same in the CF4 conditions of the present invention. Therefore, the present invention can prevent the non-uniformity of surface and damage in chalcogenides for amorphous and crystalline state.

Features of the present invention include F-based etchants, low etchant concentration (CF4<15%), low etching rate, smooth surface, and for use in etching amorphous and crystalline chalcogenides. Advantages of the invention include low etching rate for nanoscaled devices, smooth surface, and for use in etching amorphous and crystalline chalcogenides.

Therefore, the present invention supports a method to have low etching rate of chalcogenide materials and more suitable for nano-sized patterns. The present invention also supports a method to overcome the bombardment damages in pattern shape and uniformity, especially for crystalline chalcogenides.

### A Two-Step Etching Process for Phase-Change Devices

Also described herein is a CF4 based etchant which can achieve very low etching rate for phase change films and is suitable for manufacturing nano-sized pattern and overcome the compositions and bonding variation.

The chalcogenide layer is easy to etch with many kinds of gas, e.g. Cl2 or HBr, etc. due to the chemical nature of chalcogenides. Due to the high etching rate of chalcogenide by Cl2 gas, the process become difficult to control, especially in small dimensional patterns. The nonuniform reactivity in chalcogenides with etchants causes the formation of voids, compositional and bonding variations during the etching process. The present invention will provide a method to fabricate very smooth and uniform chalcogenide film and overcome the problems described above.

The nonuniform reactivity in chalcogenides with etchants cause the composition and bonding variation during the etching process, even if the etched surface looks smooth. This invention not only provides a method to manufacture smooth and uniform films but also overcomes the problems of bonding variations after etching process.

The present invention proposes using fluoride-based mixture gas as an etchant with a working pressure lower than 1 Pa in a first etching step to etch chalcogenide material, and further suitable trimmed methods by inert gas plasma as a second etching step. The fluoride-based mixture gas comprises the fluoride-based gas, inert gas and nitrogen and the combination thereof Also, the fluoride-based gas can be, for example but not limited to, difluoromethane (CH2F2), trifluoromethane (CHF3), tetrafluoromethane (CF4) and the combination thereof and the inert gas comprises Argon, Helium, Neon and the combination thereof. Moreover, the inert gas plasma used in the second etching step can be, for example but not limited to, helium plasma, argon plasma, neon plasma and the combination thereof. The present invention can be used for crystalline and amorphous state chalcogenides using, for example, PMMA/HSQ/ma-N2405 photo-resists. It should be noticed that a porous layer and a fluoride byproduct, such as SbF3, are formed on the bridge 110 in the first etching step and can prevent damage to the underlying amorphous GST during the inert gas plasma in the second etching step. This recipe for etching chalcogenides can provide smooth, uniform, and non-voids structures. In the first etching step of the present embodiment of the invention, the concentration of the fluoride-based gas can range from trace amounts to 85%, the concentration of the inert gas can range from 7% to 95%, and the concentration of the nitrogen can range from 5% to 85%. In addition, the thickness of the porous layer is about 30 nm˜300 nm and the thickness of the fluoride byproduct is about 30 nm˜300 nm.

Moreover, the first etching step is performed at room temperature with an applied frequency of about 1˜13.6 MHz, with a power of about 600˜1200 W forward, and about 0˜100 W backward. In the first etching step, the ratio of a flow rate of the nitrogen to a flow rate of the inert gas is about 7˜10. Also, in the first etching step, the flow rate of the fluoride-based gas is about 4˜15 sccm, the flow rate of the inert gas is about 45˜85 sccm and the flow rate of the nitrogen is about 0˜5 sccm. In the first etching step, the time for performing the etching process is about 20˜60 s.

In addition, in the second etching process, the forward power of the inert gas plasma is about 600˜1200 W and the backward plasma is about 0˜100 W. Also, in the second etching process, the inert gas flow rate is about 50˜120 sccm and the working pressure is about 0.5˜2 Pa/torr. Further, the time for performing the second etching process is about 20˜100 seconds.

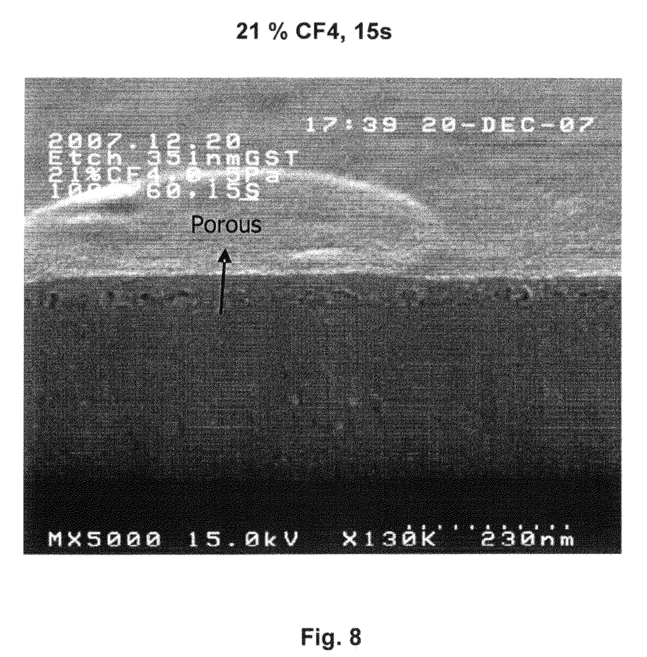

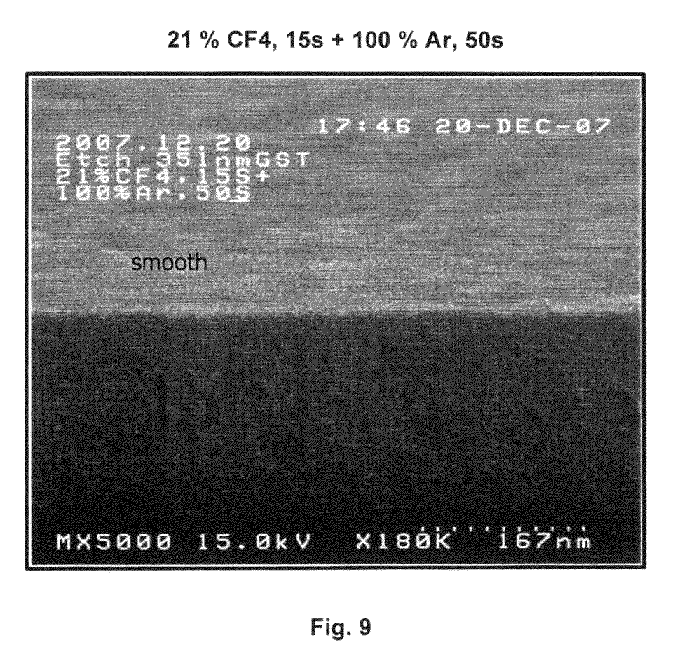

Chalcogenide films are not etched at the same rate. FIG. 8 illustrates the cross-section of amorphous GST after etching using 21% CF4, 71% Ar, and 7% N2 for 15 s showing that porous structures having voids will form during the process. FIG. 9 illustrates the cross-section after etching at 21% CF4 for 15 s and then 100% Ar for 50 s. As can be seen it is easy to form voids during the etching process. Also, the porous structures are successfully removed by the further etching process using pure Ar.

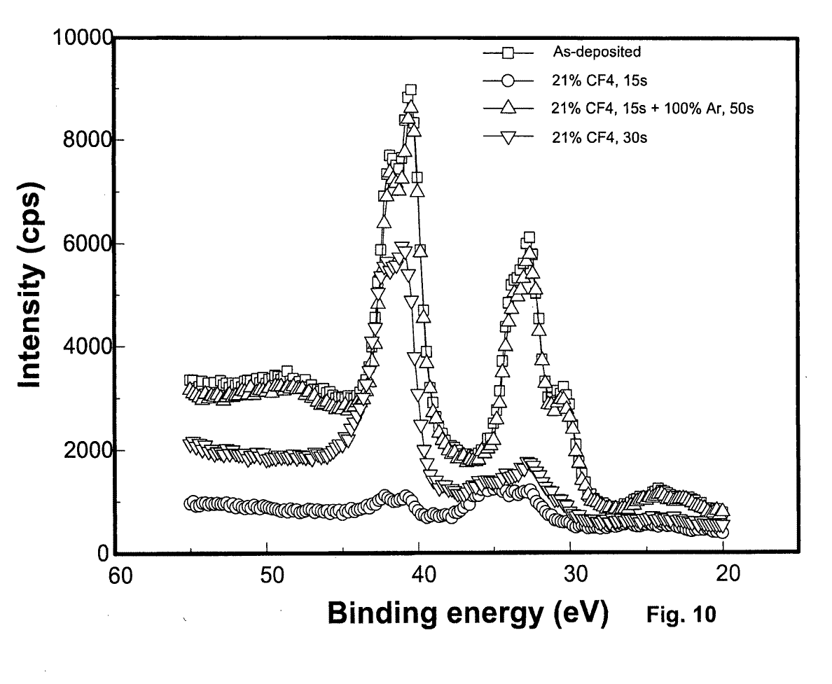

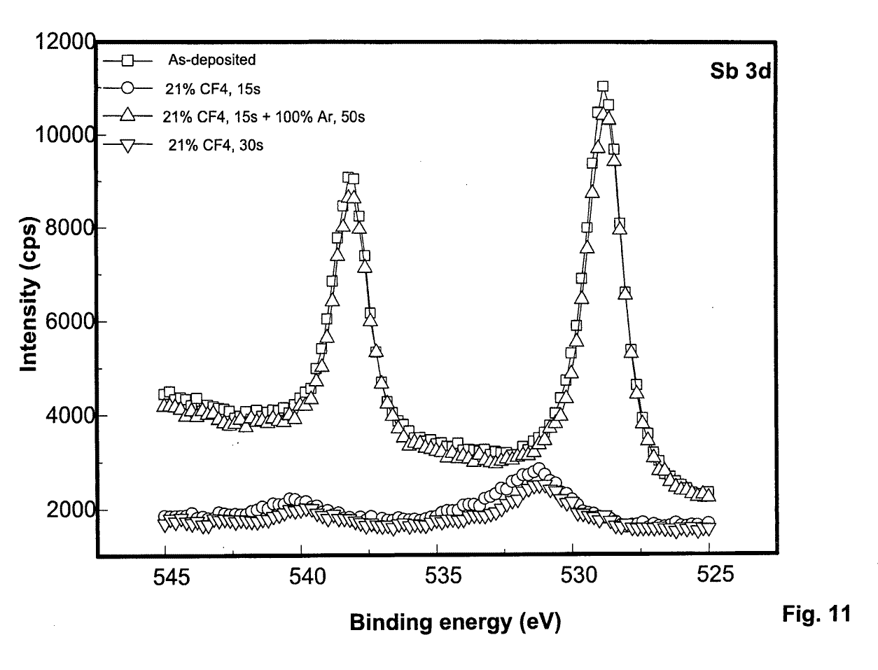

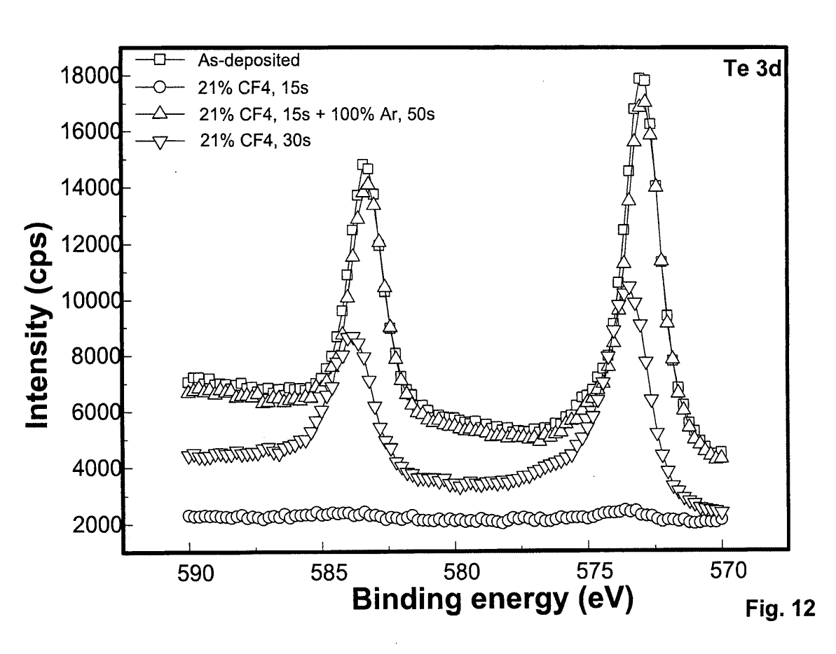

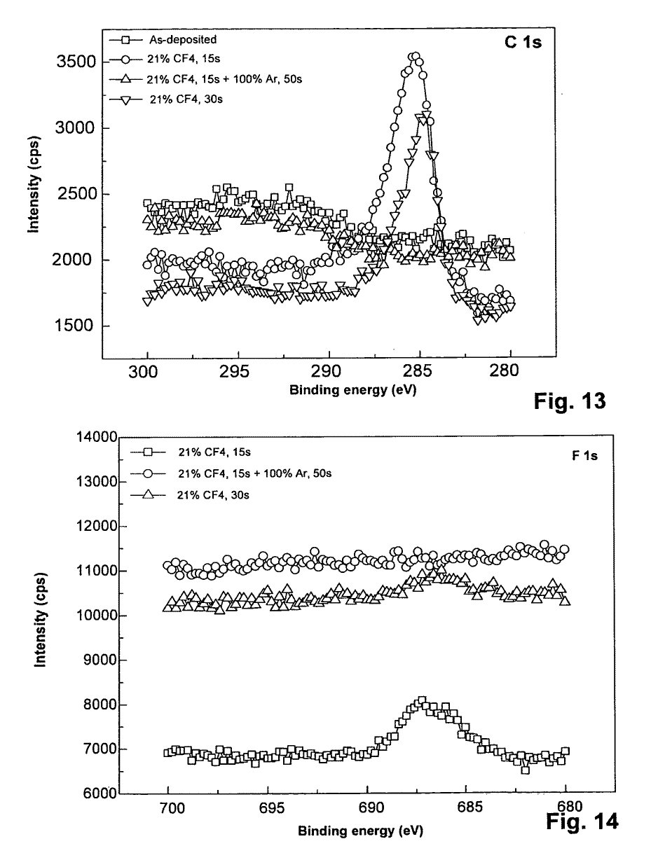

FIGS. 10-14 illustrate the binding energy vs intensity of as deposited GST, etched GST using 21% CF4 for 15 s, etched GST using 21% CF4 followed by 100% Ar for 50 s, and etched GST using 21% CF4 for 30 s. As can be seen, the bondings of etched films return to that of as-deposited one after suitable Ar trimmed methods. As can be seen in FIGS. 13-14 the C—and F-compounds were removed by the further Ar etching process. C is a very common by product in the etching process (coming from PR and “C”F4, and thus C— is in the residue. From XPS it is seen that C bonding is formed after the etching of CF4 and then removed after the Ar plasma, as do the F-compounds.

The features of the invention include a two-step etching damage free process using Ar treatments/bombardments. The advantages of the invention include a smooth surface, damage free with no by-products remaining on the surface, and controllable etching rate for nanoscaled devices.

The present invention supports a method of a low etching rate of chalcogenide materials and is suitable for nano-sized patterns. The present invention supports a method to overcome the composition and bondings variation and results in very smooth surface after etching process.

### Etching Characteristics of Nanometer-Sized Ge2Sb2Te5 for Phase Change Memory

Possible etchants for chalcogenides include Ar/Cl2, Ar/BCl3, Ar/HBr and Ar/CHF3/O2 gas. The impact on GST using Cl2-chemistry include that the etching rate for Cl2-based is fast, resulting in difficulties in controlling the etching process for nano-sized patterns. Also, compositional variations and damage of thin film GST can occur, including the formation of nonvolatile by-products.

The present invention proposes a CF4-based etchant using CF4/Ar/N2 mixed gas suitable for nano-sized GST. The table below summarizes the compounds that may be formed using the CF4 based etchant on GST chalcogenide material as described herein.

| | | Melting Point | Boiling Point |
|---|---|---|---|
| Elements | Compounds | (degrees C.) | (degrees C.) |
| Ge | GeF₂ | 110 | 130 |
| | GeF₄ | −15 | −36.5 |
| Sb | SbF₃ | 290 | 345 |
| | SbF₅ | 8.3 | 141 |
| Te | TeF₄ | 129 | 194 |
| | TeF₆ | −38 | −39 |

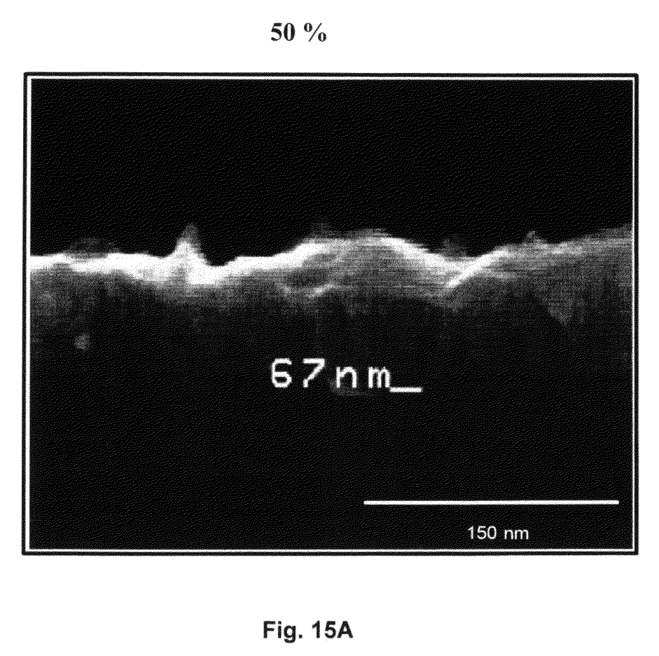

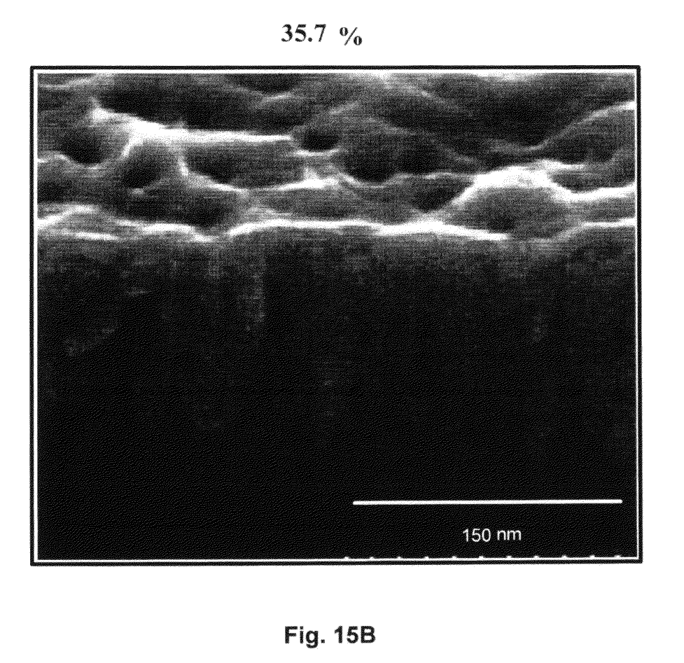

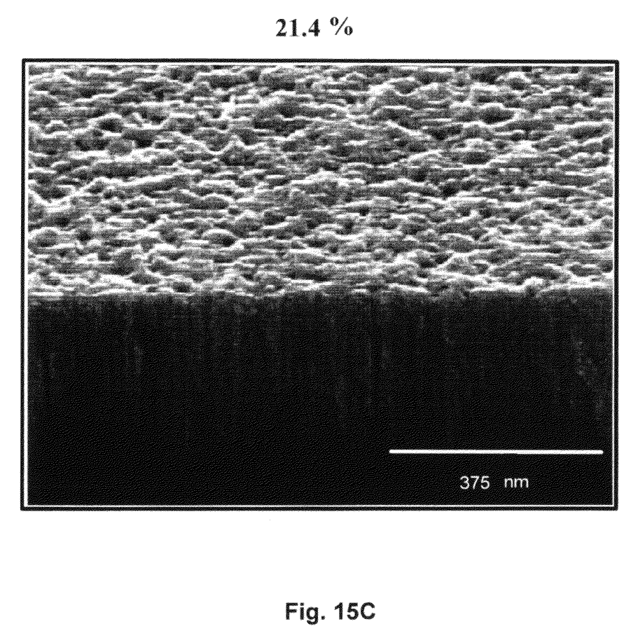

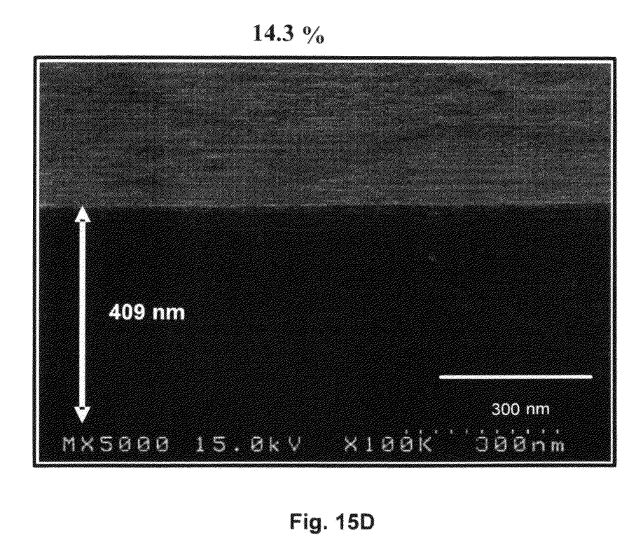

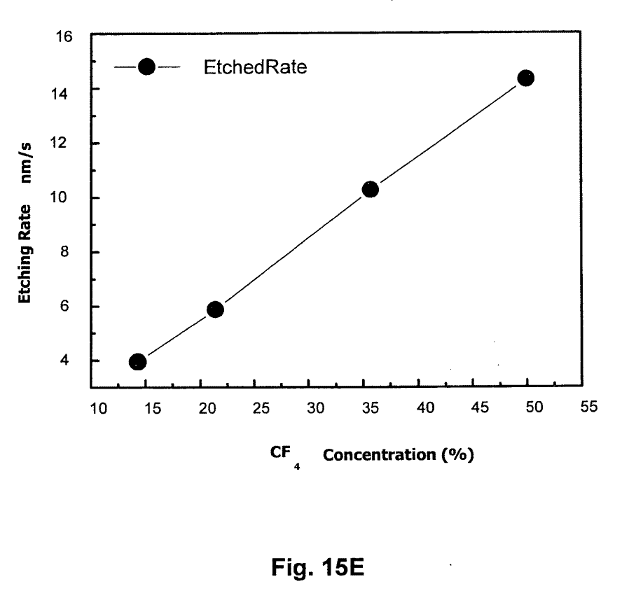

FIGS. 15A-15D shows cross-sectional views of GST etched using CF4/Ar/N2 with CF4 concentrations of 50%, 35.7%, 21.4%, and 14.3% respectively. The graph in FIG. 15E illustrates the etching rate of GST versus CF4 concentration, showing that the etching is controllable with different CF4 concentrations. As can be seen in the cross-sectional views, and the CF4 concentration decreases the uniformity increases.

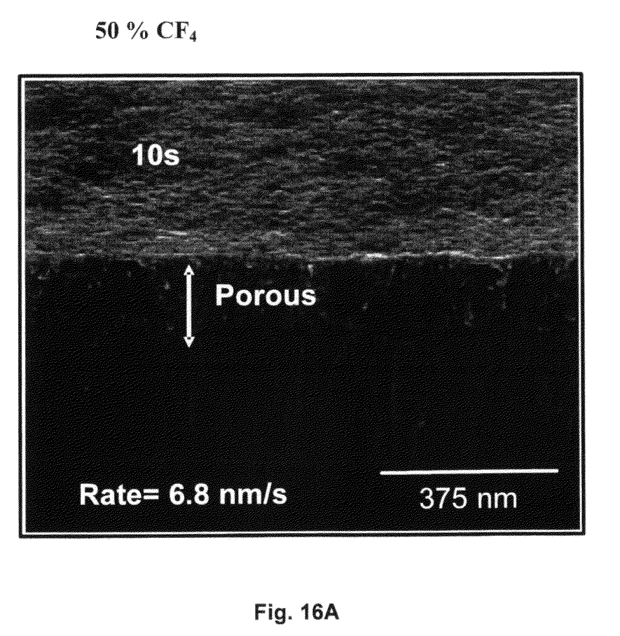

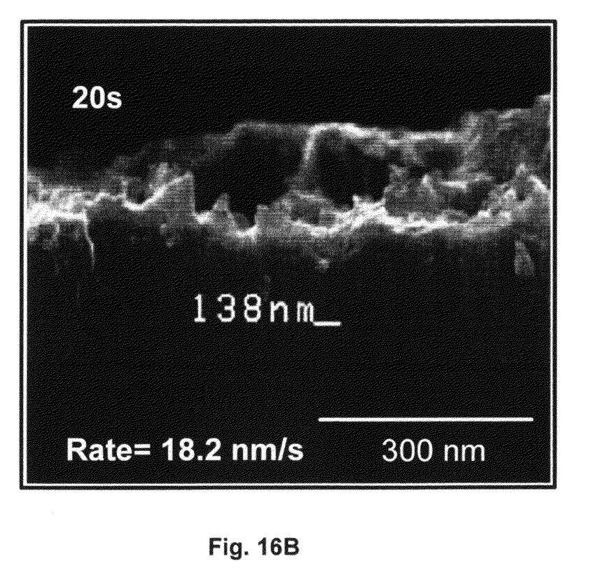

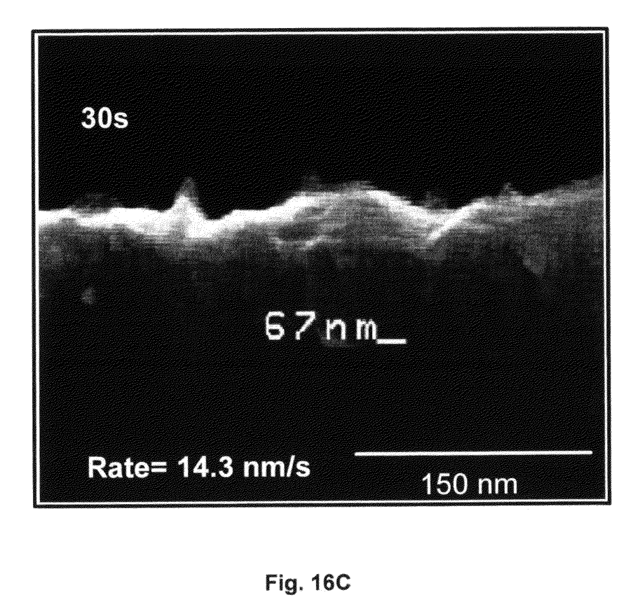

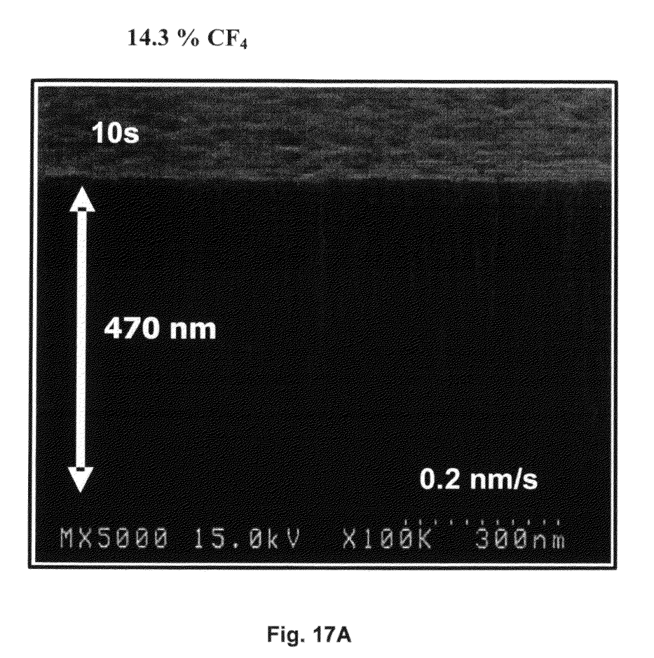

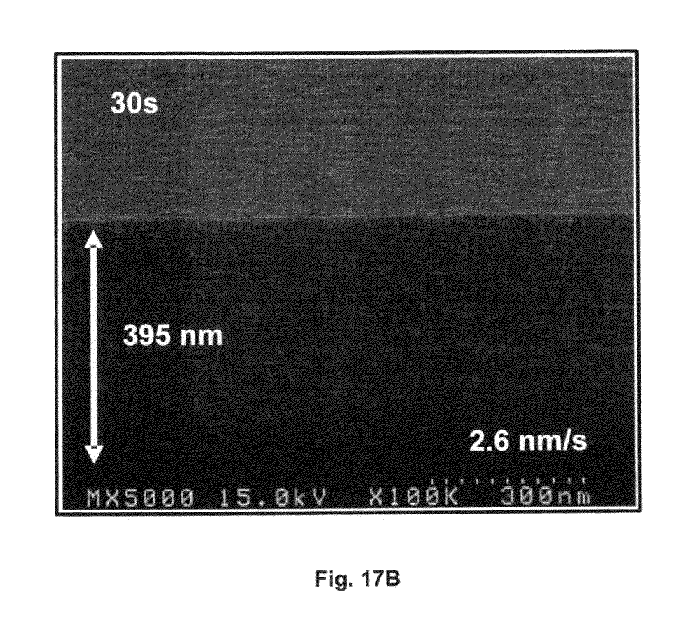

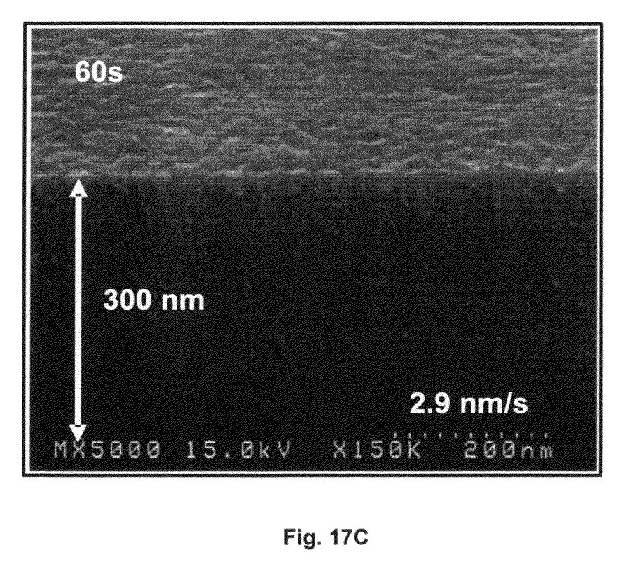

FIGS. 16-17 illustrate the etching rate of 50% CF4 and 14.3% CF4 respectively for times of 10 s, 20 s, and 30 s. For 50% CF4 the etching rate after 10 s is 6.8 nm/s as shown in FIG. 16A, after 20 s is 18.2 nm/s as shown in FIG. 16B, and after 30 s is 14.3 nm/s as shown in FIG. 16C. For 14.3% CF4 the etching rate after 10 s is 0.2 nm/s as shown in FIG. 17A, after 30 s is 2.6 nm/s as shown in FIG. 17B, and after 60 s is 2.9 nm/s as shown in FIG. 17C. Thus, GST films are not etched at the same rate as with high CF4 concentration.

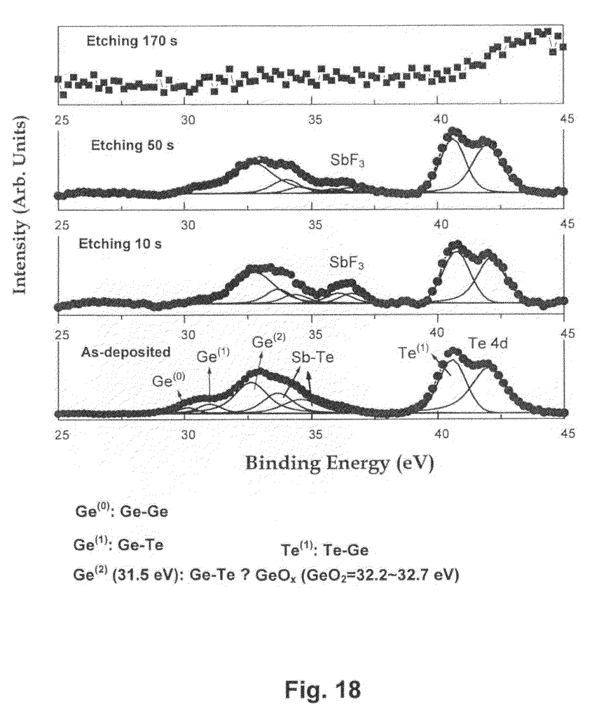

FIG. 18 illustrates the XPS Spectra of GST films as-deposited (amorphous), after etching for 10 s, etching for 50 s, and etching for 170 s. The metallic bondings (Ge—Te or Ge—Sb) are dominating in the as-deposited GST films. Ge homopolar bondings are etched first and then Ge—Sb or Ge—Te bondings are etched afterwards. There are no by-products for Ge and Te with fluoride radicals. But Sb is easy to form SbF3 compounds during the etching process. The peak of Te 4d does not significantly change during the etching process, indicating that Te is difficult to etch. The Ge(2) at 31.5 eV may be Ge—Te and/or GeOx bonding.

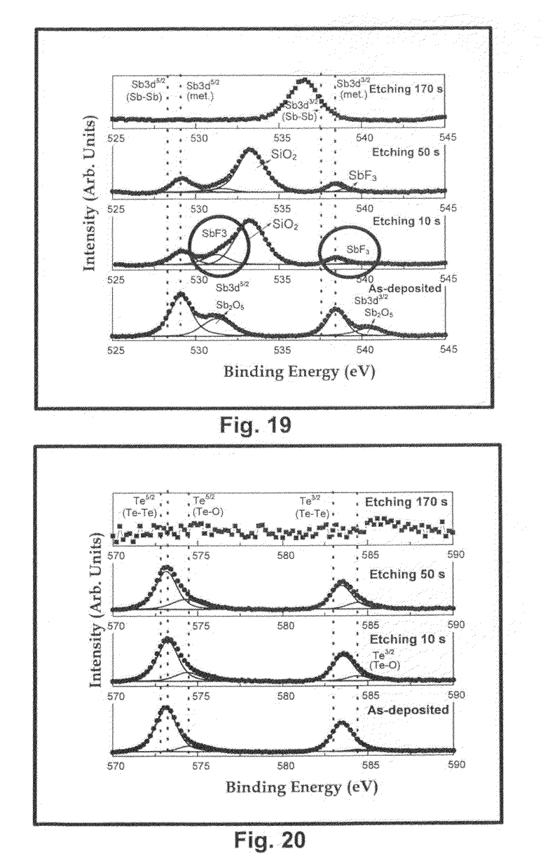

FIGS. 19 and 20 illustrate the XPS Spectra of Sb 3d and Te3d respectively. The Sb homopolar peak (Sb—Sb) peak does not appear; instead, there appears Sb metallic bondings (Sb—Te or Sb—Ge) of 3d. Sb reacts with fluoride radicals to form SbF3 compound, indicating that Sb is the easiest element in GST films to be etched. There is no significant change on Te 3d peaks, thus etching of Te in GST films is the rate limiting step with CF4 etchant.

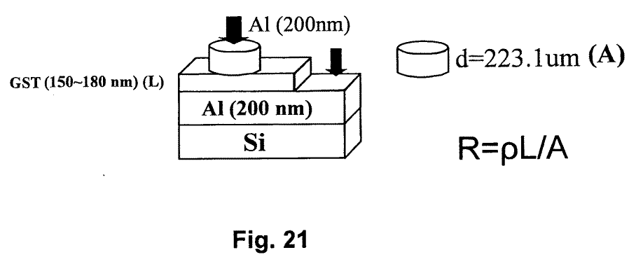

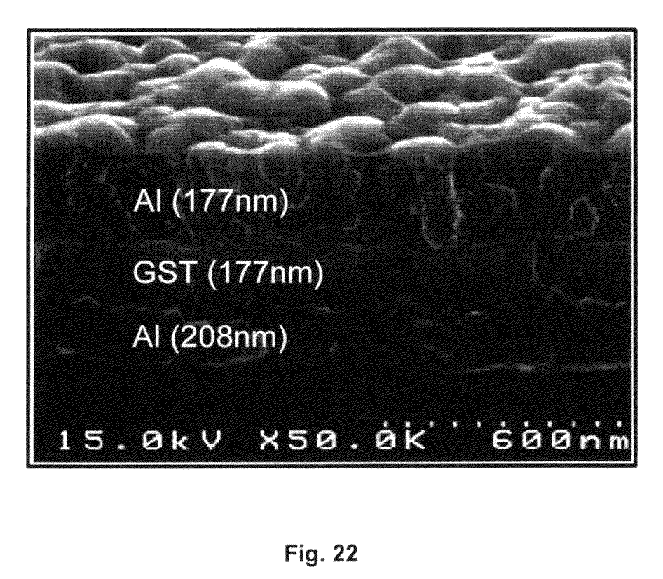

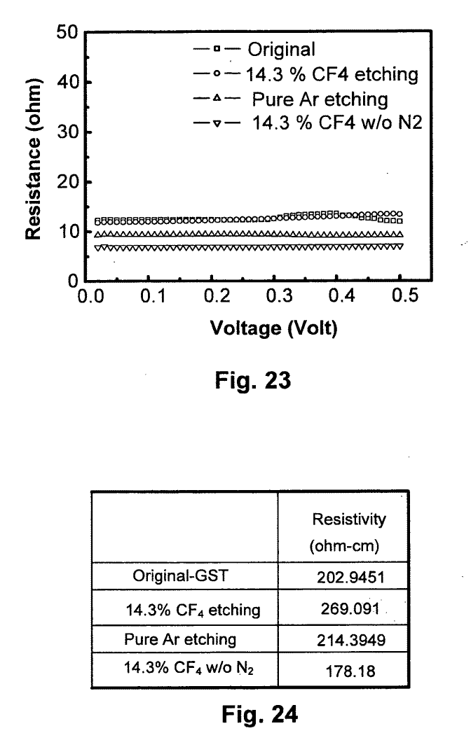

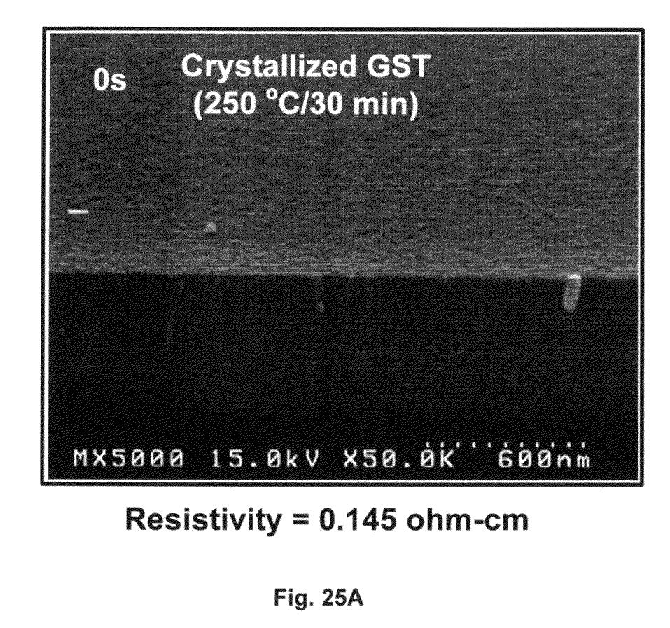

FIG. 21 illustrates a simplified cross-sectional view of the structure used for measuring the IV characteristics of amorphous GST. In FIG. 21, an first aluminum element having a diameter of 223.1 μm having a thickness of 200 nm is on a GST layer having a thickness of between about 150 to 180 nm. A second aluminum element having a thickness of 200 nm is under the GST layer, and Si is under the second aluminum element. FIG. 22 illustrates a cross-sectional view of one of the actual devices. FIG. 23 illustrates the measured voltage versus resistance characteristics of original GST, etched GST using CF4/Ar/N2 with 14.3% CF4, etched GST using pure Ar etching, and etched GST using 14.3% CF4 without N2, while FIG. 24 shows the measured resistivity of each for a voltage of 0.1 Volts. The resistance is related to the thickness of the film and the thicknesses of the samples are not identical. The IV characteristics of GST do not change a lot after dry etch process using the recipe described herein.

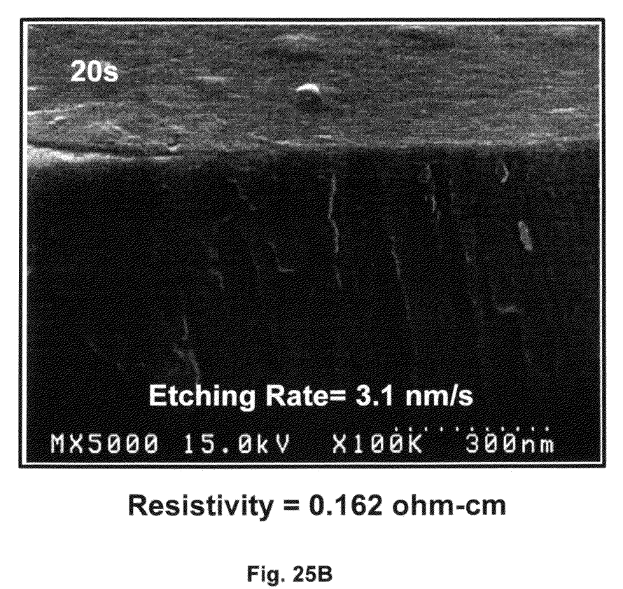

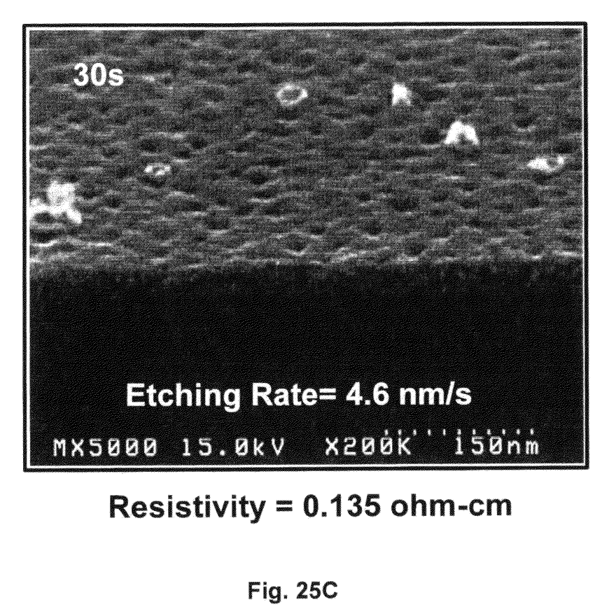

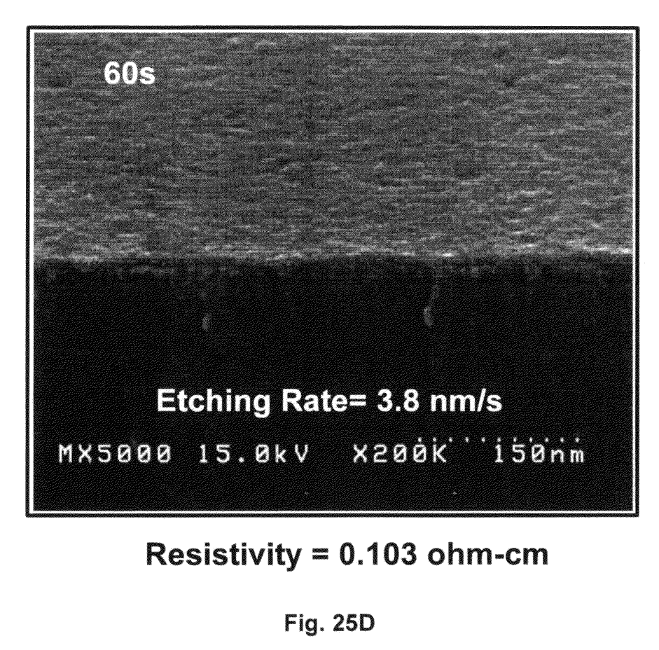

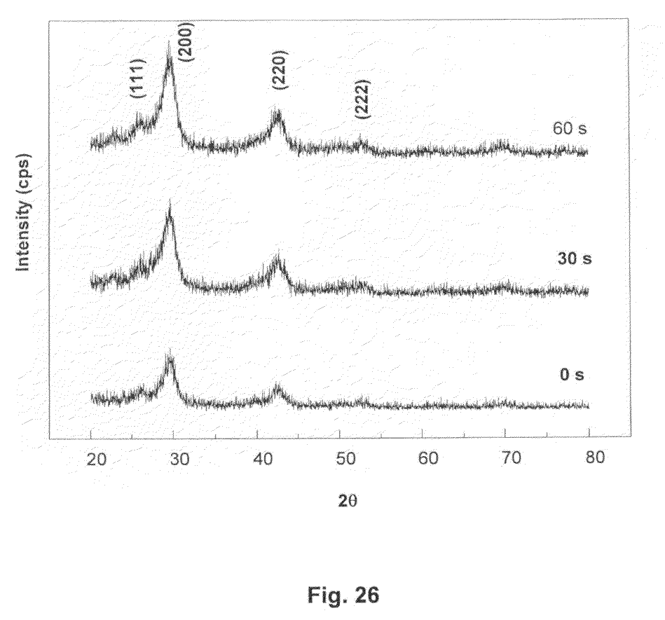

FIGS. 25A-25D illustrates cross-sectional views of crystalline GST etched using 14.3% CF4. For crystallized GST (250 oC/30 min) the resistivity at 0 seconds etching is 0.145 ohm-cm as shown in FIG. 25A. After 20 s of etching the etching rate is 3.1 nm/s and the resistivity was 0.162 ohm-cm as shown in FIG. 25B. After 30 s the etching rate is 4.6 nm/s and the resistivity was 0.135 ohm-cm as shown in FIG. 25C. After 60 s the etching rate was 3.8 nm/s and the resistivity was 0.103 ohm-cm as shown in FIG. 25D. FIG. 26 illustrates 2θ versus intensity at 0 seconds, 30 seconds of etching, and 60 seconds of etching, and the (111), (200, (220), and (222) numbers in the figure indicate the planes of the crystal. The structures and the resistivity did not change after CF4-based plasma etching. Also, the etching rate for crystalline is greater than the etching rate for amorphous for CF4 etching.

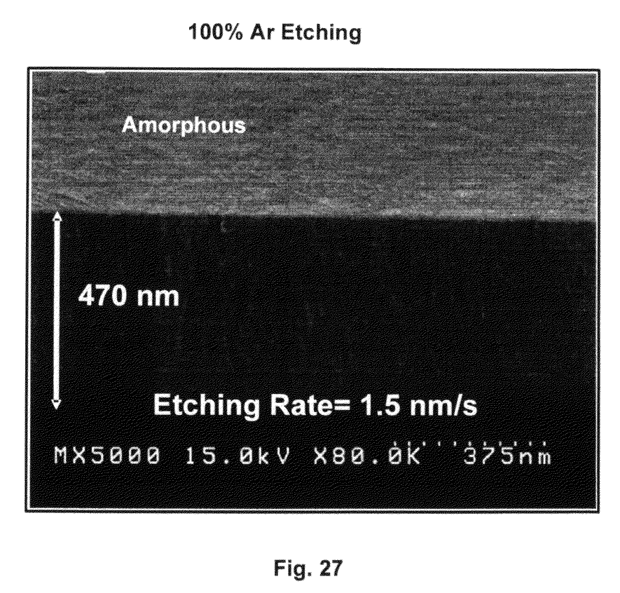

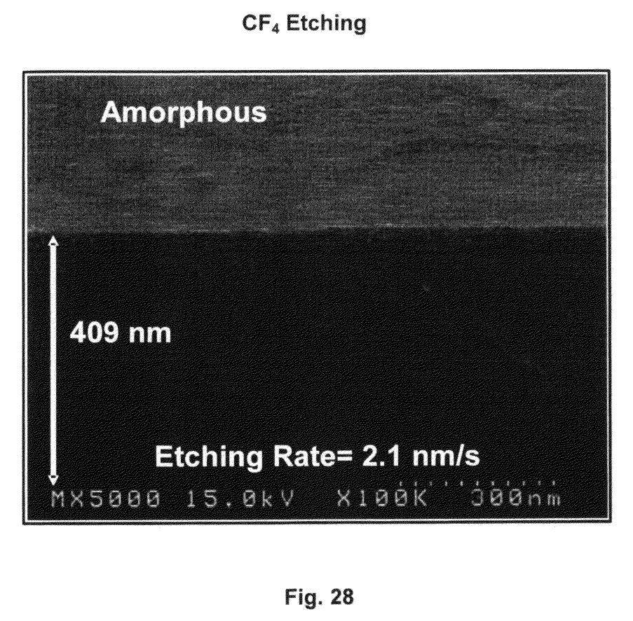

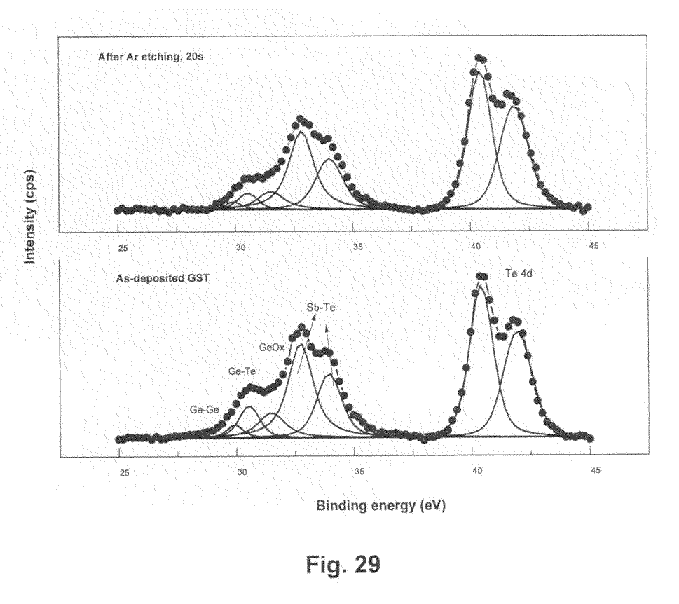

FIG. 27 is a cross-section of amorphous GST etched using 100% Ar resulting in an etching rate of 1.5 nm/s. FIG. 28 is a cross-section of amorphous GST etched using CF4/Ar/N2 as described herein, resulting in an etching rate of 2.1 nm/s. FIG. 29 illustrates the XPS data of the as-deposited GST and the etched GST after Ar etching for 20 s. Ar etching does not change the bondings or damage the films at amorphous state.

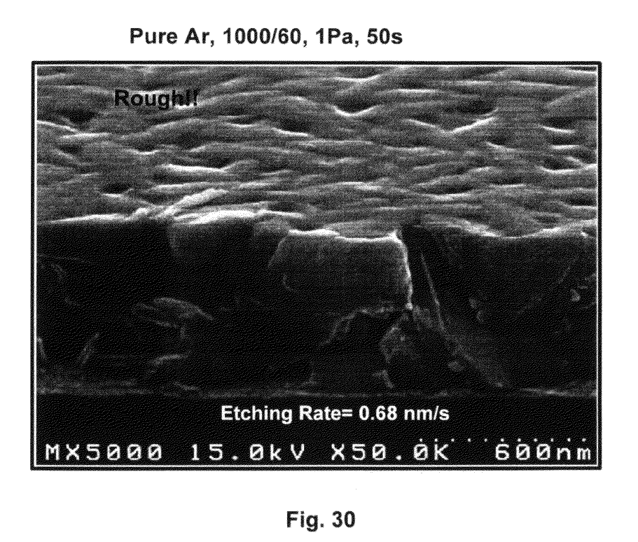

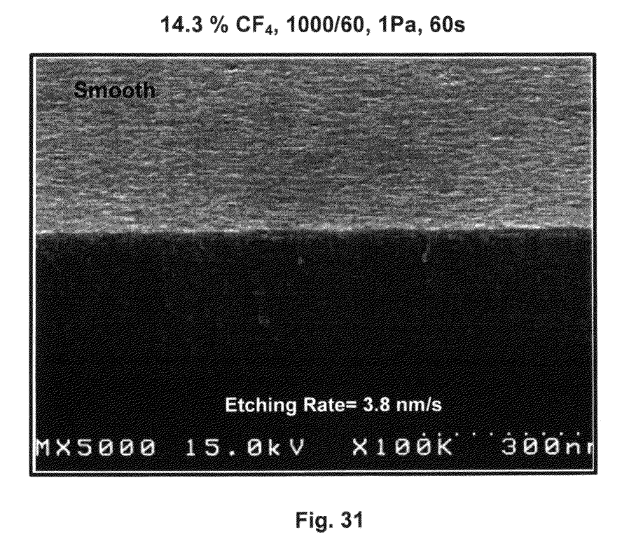

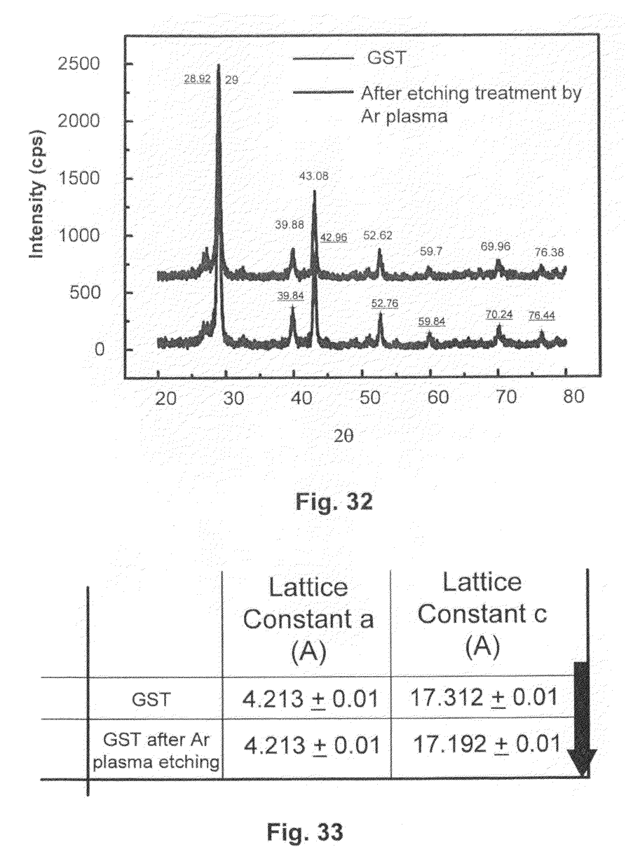

FIG. 30 illustrates a cross-section of crystalline GST etched using Pure Ar, 1000/60, 1 Pa, 50 s resulting in an etch rate of 0.68 nm/s, illustrating the etching damage by Ar bombardment. FIG. 31 illustrates a cross-section of crystalline GST etched using CF4/Ar/N2 with 14.3% CF4, 1000/60, 1 Pa, 60 s resulting in an etch rate of 3.8 nm/s and a smooth surface. FIG. 32 shows 2θ versus intensity for crystalline GST and for crystalline GST after etching treatment by Ar plasma, and FIG. 33 shows the change in lattice constant c after the Ar plasma etching.

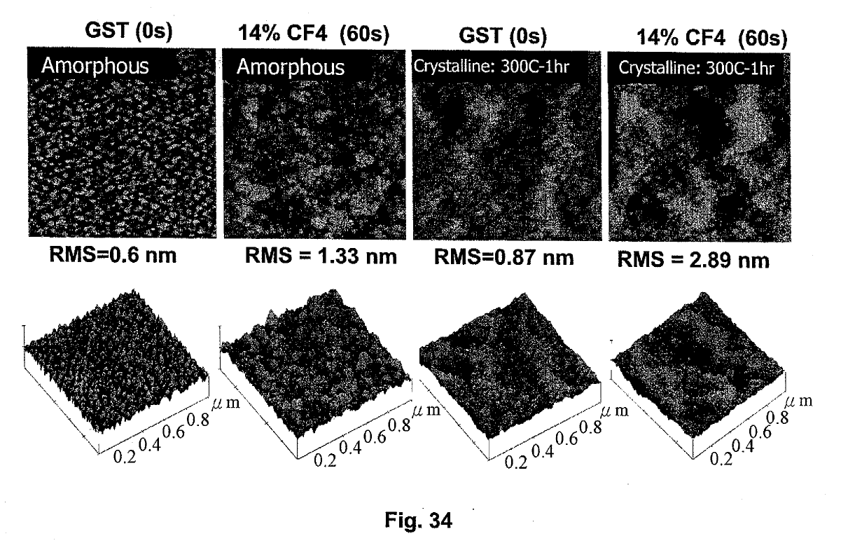

FIG. 34 shows the crystallization behavior of amorphous and crystalline GST at 0 s and after 60 s of etching using CF4/Ar/N2 with 14% CF4 as described herein. For amorphous GST at 0 s the surface roughness RMS=0.6nm, and after 60 s of etching using 14% CF4 the RMS is 1.33 nm. For crystalline GST (300 oC for 1 hour) the RMS is 0.87 nm, and after 60 s of etching using 14% CF4 as described herein the RMS is 2.89 nm. The crystallization behavior did not have significant change after etching treatments, having confirmed by crystallinity by time-resolved XRD.

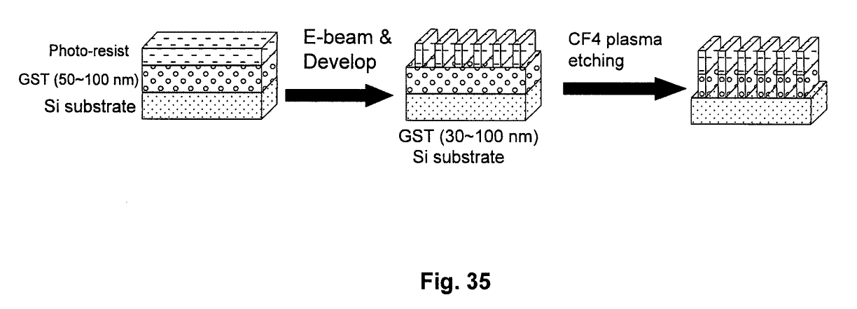

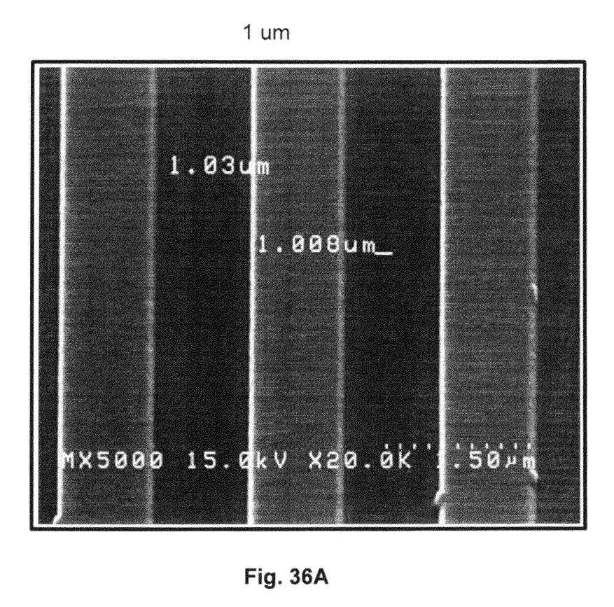

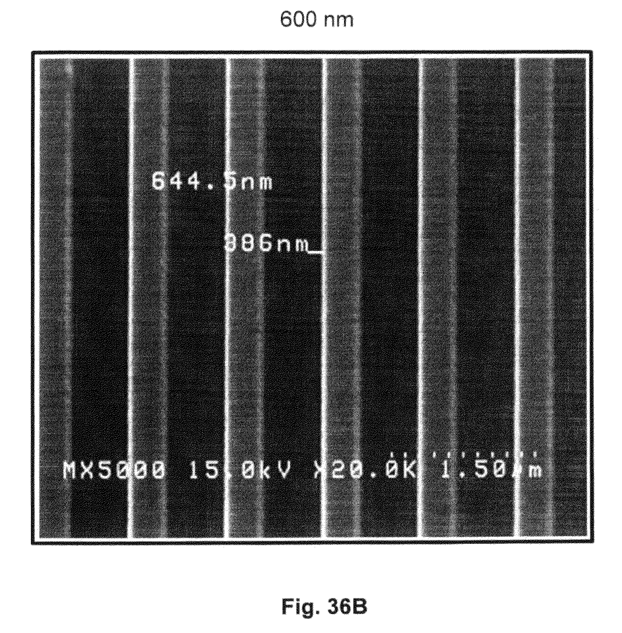

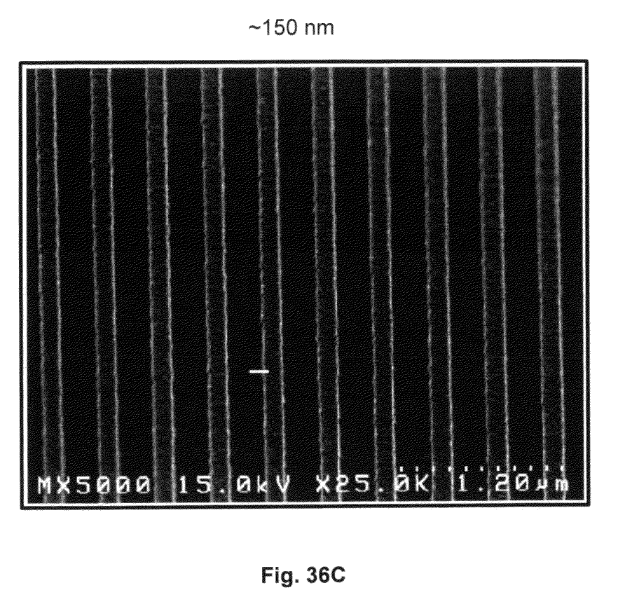

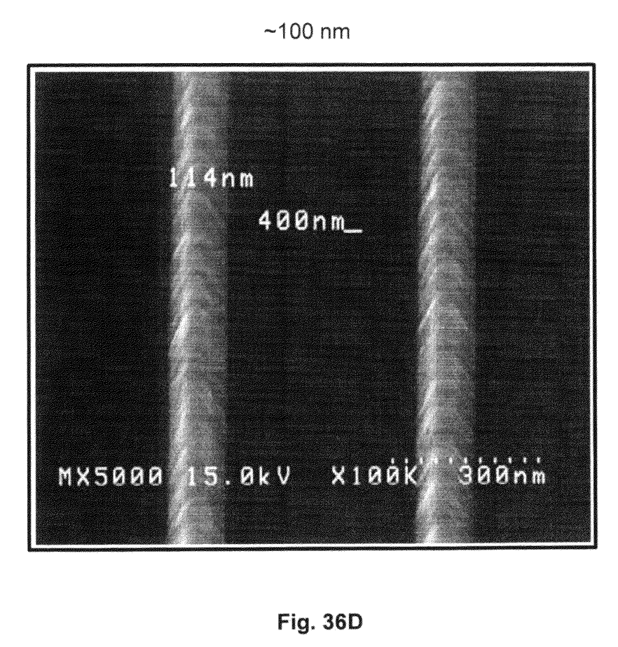

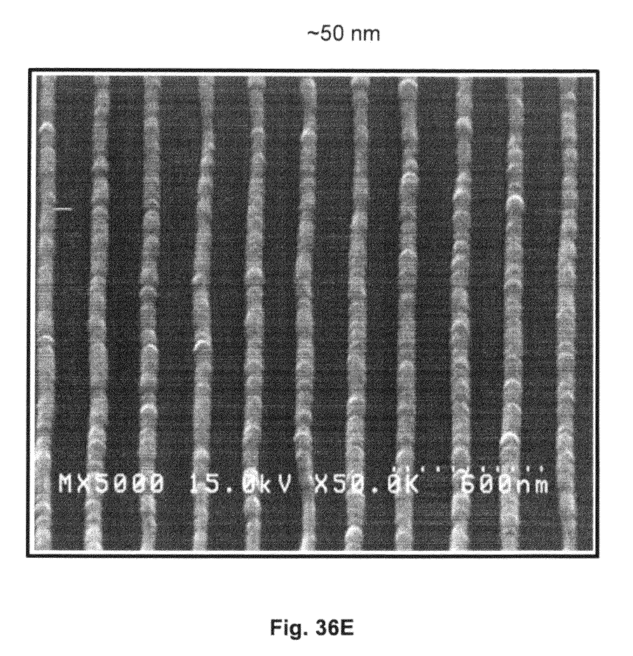

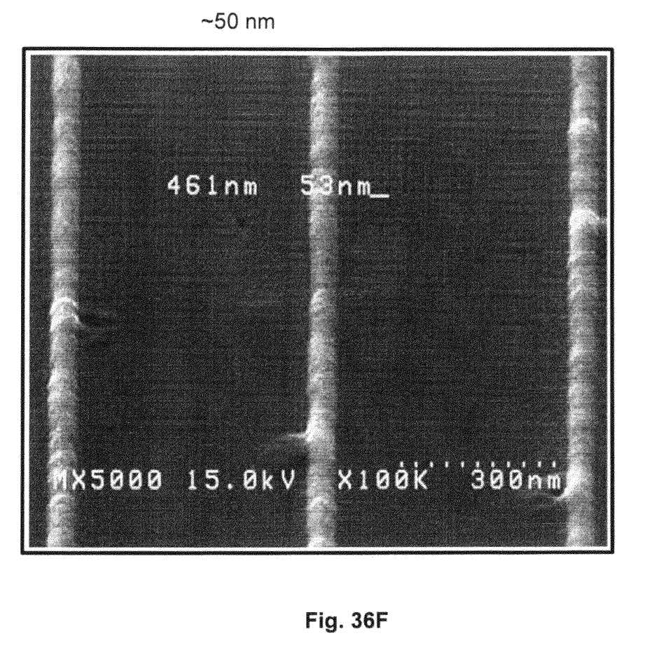

FIG. 35 illustrates the process for forming nano-sized patterns using the techniques described herein. A layer of photoresist is first patterned using E-beam lithography and developed, followed by etching using CF4 plasma etching. The CF4 plasma etching may remove the HSQ but the patterned GST is very well controlled. FIGS. 36A-36F show the results of GST lines with features sizes from 1 μm to 50 nm successfully manufactured using CF4/Ar/N2 as described herein.

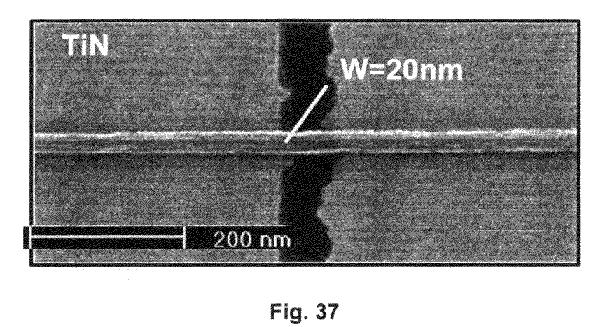

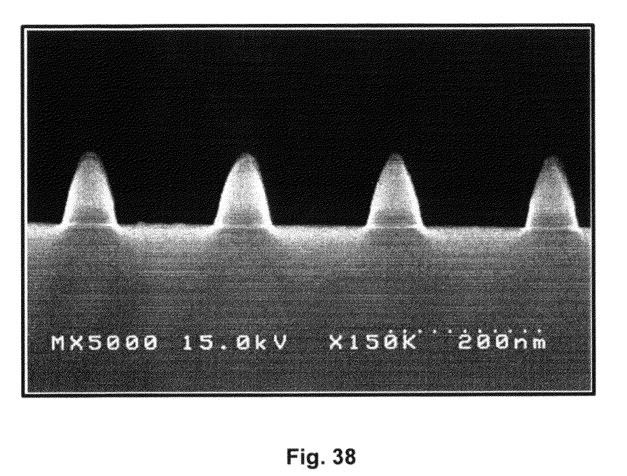

FIG. 37 illustrates a bridge type cell illustrating the types of devices that can be formed using the techniques described herein and is milled by Ar only. See Y C. Chen, et al., IEDM Tech. Dig., 777 (2006), incorporated by reference herein. FIG. 38 illustrates a cross-sectional view of patterned GST using CF4 etching as described herein having a thickness of 30 nm using PR of Ma-N2405, baked at 135 degrees C., resulting in lines having a critical dimension of approximately 50 nm.

The extremely nano-sized devices were successfully manufactured by the combination of electron-beam lithography and pattern transfer by Ar ion-milling process and by CF4 dry etching process as well.

As described above, dry etching characteristics for GST using CF4 based plasma was investigated. The etching rate is controllable for device manufacturing. The formation of nonvolatile by-products, SbF3, needs to be removed by Ar plasma. The nonuniform reactivity in GeSbTe systems cause the bondings variations during etching process. The Sb and Te are the easiest and the most difficult element to be etched in the GST thin films, respectively. There is no significant changes in electrical resistivity, structures, and crystallization behavior after CF4 plasma etching using processed described herein. Pure Ar etching is damage free for a-GST, but significantly impacts c-GST. Sub 50 nm line are successfully made with the CF4/Ar/N2 recipe.

The results herein show etching of the chalcogenide alloy Ge2Sb2Te5 using CF4/Ar/N2, although it will be understood that the present invention is not limited to etching Ge2Sb2Te5. As further examples, GeTe—Sb2Te3, GexSby, SbxTey, and Sb based materials can be etched since they are all metals and they contain Sb elements.

Embodiments may also include chalcogenide based materials described below. Chalcogens include any of the four elements oxygen (O), sulfur (S), selenium (Se), and tellurium (Te), forming part of group VIA of the periodic table. Chalcogenides comprise compounds of a chalcogen with a more electropositive element or radical. Chalcogenide alloys comprise combinations of chalcogenides with other materials such as transition metals. A chalcogenide alloy usually contains one or more elements from group IVA of the periodic table of elements, such as germanium (Ge) and tin (Sn). Often, chalcogenide alloys include combinations including one or more of antimony (Sb), gallium (Ga), indium (In), and silver (Ag). Many phase change based memory materials have been described in technical literature, including alloys of: Ga/Sb, In/Sb, In/Se, Sb/Te, Ge/Te, Ge/Sb/Te, In/Sb/Te, Ga/Se/Te, Sn/Sb/Te, In/Sb/Ge, Ag/In/Sb/Te, Ge/Sn/Sb/Te, Ge/Sb/Se/Te and Te/Ge/Sb/S. In the family of Ge/Sb/Te alloys, a wide range of alloy compositions may be workable. The compositions can be characterized as TeaGebSb100−(a+b). One researcher has described the most useful alloys as having an average concentration of Te in the deposited materials well below 70%, typically below about 60% and ranged in general from as low as about 23% up to about 58% Te and most preferably about 48% to 58% Te. Concentrations of Ge were above about 5% and ranged from a low of about 8% to about 30% average in the material, remaining generally below 50%. Most preferably, concentrations of Ge ranged from about 8% to about 40%. The remainder of the principal constituent elements in this composition was Sb. These percentages are atomic percentages that total 100% of the atoms of the constituent elements. (Ovshinsky U.S. Pat. No. 5,687,112 patent, cols. 10-11.) Particular alloys evaluated by another researcher include Ge2Sb2Te5, GeSb2Te4 and GeSb4Te7 (Noboru Yamada, “Potential of Ge—Sb—Te Phase-Change Optical Disks for High-Data-Rate Recording”, SPIE v. 3109, pp. 28-37 (1997).) More generally, a transition metal such as chromium (Cr), iron (Fe), nickel (Ni), niobium (Nb), palladium (Pd), platinum (Pt) and mixtures or alloys thereof may be combined with Ge/Sb/Te to form a phase change alloy that has programmable resistive properties. Specific examples of memory materials that may be useful are given in Ovshinsky '112 at columns 11-13, which examples are hereby incorporated by reference.

Chalcogenides and other phase change materials are doped with impurities in some embodiments to modify conductivity, transition temperature, melting temperature, and other properties of memory elements using the doped chalcogenides. Representative impurities used for doping chalcogenides include nitrogen, silicon, oxygen, silicon dioxide, silicon nitride, copper, silver, gold, aluminum, aluminum oxide, tantalum, tantalum oxide, tantalum nitride, titanium and titanium oxide. See, e.g., U.S. Pat. No. 6,800,504, and U.S. Patent Application Publication No. U.S. 2005/0029502.

Phase change alloys are capable of being switched between a first structural state in which the material is in a generally amorphous solid phase, and a second structural state in which the material is in a generally crystalline solid phase in its local order in the active channel region of the cell. These alloys are at least bistable. The term amorphous is used to refer to a relatively less ordered structure, more disordered than a single crystal, which has the detectable characteristics such as higher electrical resistivity than the crystalline phase. The term crystalline is used to refer to a relatively more ordered structure, more ordered than in an amorphous structure, which has detectable characteristics such as lower electrical resistivity than the amorphous phase. Typically, phase change materials may be electrically switched between different detectable states of local order across the spectrum between completely amorphous and completely crystalline states. Other material characteristics affected by the change between amorphous and crystalline phases include atomic order, free electron density and activation energy. The material may be switched either into different solid phases or into mixtures of two or more solid phases, providing a gray scale between completely amorphous and completely crystalline states. The electrical properties in the material may vary accordingly.

Phase change alloys can be changed from one phase state to another by application of electrical pulses. It has been observed that a shorter, higher amplitude pulse tends to change the phase change material to a generally amorphous state. A longer, lower amplitude pulse tends to change the phase change material to a generally crystalline state. The energy in a shorter, higher amplitude pulse is high enough to allow for bonds of the crystalline structure to be broken and short enough to prevent the atoms from realigning into a crystalline state. Appropriate profiles for pulses can be determined, without undue experimentation, specifically adapted to a particular phase change alloy. In following sections of the disclosure, the phase change material is referred to as GST, and it will be understood that other types of phase change materials can be used. A material useful for implementation of a PCRAM described herein is Ge2Sb2Te5.

Other programmable resistive memory materials may be used in other embodiments of the invention, including N2 doped GST, GexSby, or other material that uses different crystal phase changes to determine resistance.

An exemplary method for forming chalcogenide material uses PVD-sputtering or magnetron-sputtering method with source gas(es) of Ar, N2, and/or He, etc. at the pressure of 1 mTorr˜100 mTorr. The deposition is usually done at room temperature. A collimator with an aspect ratio of 1˜5 can be used to improve the fill-in performance. To improve the fill-in performance, a DC bias of several tens of volts to several hundreds of volts is also used. On the other hand, the combination of DC bias and the collimater can be used simultaneously.

A post-deposition annealing treatment in a vacuum or in an N2 ambient is optionally performed to improve the crystallize state of chalcogenide material. The annealing temperature typically ranges from 100° C. to 400° C. with an anneal time of less than 30 minutes.

The etching techniques described herein can be used in the manufacturing of phase change memory cell structures such as those disclosed in U.S. Pat. No. 7,321,130, which is attached hereto and incorporated by reference herein.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention.

What is claimed is:

1. A method for forming a phase change material layer comprising:
providing a phase change material layer; and
etching the phase change material layer with an etchant comprising a fluoride-based gas having a concentration up to 85% of a total volume of the etchant.

2. The method of claim 1 further comprising etching the phase change material layer with plasma.

3. The method of claim 2, wherein the plasma is selected from a group including helium plasma, argon plasma, neon plasma and the combination thereof.

4. The method of claim 2, wherein a porous layer and a fluoride byproduct are formed over the etched phase change material layer during the etching step with the etchant.

5. The method of claim 4, wherein the porous layer and the fluoride byproduct are removed during the etching step with plasma.

6. The method of claim 1, wherein the etchant further comprises an inert gas and nitrogen.

7. The method of claim 6, wherein the inert gas is selected from a group including Argon, Helium, Neon and the combination thereof.

8. The method of claim 6, wherein the concentration of the inert gas is about 7% to 95%.

9. The method of claim 6, wherein the concentration of the nitrogen is about 5% to 85%.

10. The method of claim 1, wherein the fluoride-based gas is selected from a group including difluoromethane, trifluoromethane, tetrafluoromethane and the combination thereof.

11. The method of claim 1, wherein the step for etching the phase change material layer is performed at a working pressure less than 1 Pa.

12. The method of claim 1, wherein an applied frequency of the step for etching the phase change material layer is about 113.6 MHz.

13. The method of claim 1, wherein a forward power of the step for etching the phase change material layer is about 600˜1200 W.

14. The method of claim 1, wherein a backward power of the step for etching the phase change material layer is about 0˜100 W.

15. A method for forming a phase change material layer, comprising:
providing a phase change material layer; and
etching the phase change material layer with an etchant comprising a fluoride-based gas having a concentration less than 15% of a total volume of the etchant.

16. The method of claim 15, wherein the etchant further comprises an inert gas and nitrogen.

17. The method of claim 16, wherein the inert gas is selected from a group including Argon, Helium, Neon and the combination thereof.

18. The method of claim 15, wherein the fluoride-based gas is selected from a group including difluoromethane, trifluoromethane, tetrafluoromethane and the combination thereof.

19. The method of claim 15, wherein the step for etching the phase change material layer is performed at a working pressure less than 1 Pa.

20. The method of claim 15, wherein the etching rate of the step for etching the phase change material layer is about 1.5˜4 nm/s.

21. The method of claim 15, wherein an applied frequency of the step for etching the phase change material layer is about 1˜13.6 MHz.

22. The method of claim 15, wherein a forward power of the step for etching the phase change material layer is about 600˜1200 W.

23. The method of claim 15, wherein a backward power of the step for etching the phase change material layer is about 0˜100 W.
